(19) United States
(12) Patent Application Publication
(10) Pub. No.: US 2026/0198088 A1
(43) Pub. Date: Jul. 9, 2026

(54) HYBRID CHANNEL SEMICONDUCTOR DEVICE AND METHOD OF FABRICATING THE SAME

(71) Applicant: TAIWAN SEMICONDUCTOR MANUFACTURING COMPANY, LTD., Hsinchu (TW)

(72) Inventors: Jiann-Tyng TZENG, Hsinchu (TW); Jian-Hao CHEN, Hsinchu (TW); Hung-Li CHIANG, Hsinchu (TW); Wei-Cheng LIN, Hsinchu (TW)

(21) Appl. No.: 19/192,729

(22) Filed: Apr. 29, 2025

Related U.S. Application Data
(60) Provisional application No. 63/741,651, filed on Jan. 3, 2025.

(51) Int. Cl. H10D 84/90; H10D 89/10

(52) U.S. Cl. CPC H10D 84/927; H10D 84/953; H10D 89/10

(57) ABSTRACT

A semiconductor device includes a first source/drain structure; a second source/drain structure spaced from the first source/drain structure in a first direction; a first portion of a first channel structure adjacent the first source/drain structure at a first height; a second portion of the first channel structure adjacent the second source/drain structure, the second portion of the first channel structure being at the first height and spaced from the first portion of the first channel structure in the first direction; an insulating structure between the first and second portions of the first channel structure, the insulating structure being at the first height and having a thickness that is at least as thick as either of the first and second portions of the first channel structure; and a second channel structure between the first and second source/drain structures at a second height, the second height being less than the first height.

### PRIORITY

This application claims the benefit of U.S. Provisional Application No. 63/741,651, filed Jan. 3, 2025, which is herein incorporated by reference in its entirety.

### BACKGROUND

As semiconductor devices have been reduced in size and increased in complexity, transistors using stacked channels have been employed to increase transistor density and performance. However, using identical transistor structures for all circuits of a semiconductor device can have drawbacks such as larger than desired circuit power consumption.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a semiconductor device according to some embodiments.

FIG. 2 is a cross-sectional view showing capacitance effects in a semiconductor device according to some embodiments.

FIG. 3 is a cross-sectional view showing capacitance effects in a semiconductor device according to some embodiments.

FIG. 4 is a cross-sectional view of a semiconductor device according to some embodiments.

FIG. 5 is a flowchart of a method of fabricating a semiconductor device according to some embodiments.

FIGS. 6A, 6B, 6C, 6D-1, and 6D-2 are cross-sectional views of stages in a method of fabricating a semiconductor device according to some embodiments.

FIGS. 7A, 7B, 7C, and 7D are cross-sections of semiconductor devices according to some embodiments.

FIGS. 8A and 8B are cross-sectional views of stages in a method of fabricating a semiconductor device according to some embodiments.

FIGS. 9A, 9B, 9C-1, 9C-2, and 9C-3 are layout diagrams of a processor and a system-on-chip (SoC) according to some embodiments.

FIG. 10 is a flowchart of a method of manufacturing an IC device according to some embodiments.

FIG. 11 is a block diagram of an IC device design system according to some embodiments.

FIG. 12 is a block diagram of an IC manufacturing system, and an IC manufacturing flow associated therewith, according to some embodiments.

### DETAILED DESCRIPTION

The following disclosure provides many different embodiments, or examples, for implementing different features of the provided subject matter. Specific examples of components, materials, values, steps, operations, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, transistors having a first number of vertically stacked channels and transistors have a different, second number of vertically stacked channels are included within a same semiconductor device, die, layout, row, circuit, or the like. Providing transistors having differing numbers of channels aids in design flexibility and allows for power savings while maintaining performance. In some embodiments, a transistor having a first number of vertically stacked channels has an uppermost channel that is inoperative or disabled relative to a transistor having a second number of vertically stacked channels. In some embodiments, an insulating structure or dielectric structure is formed in at least a part of a region that would otherwise be occupied by an uppermost channel structure in a transistor having a relatively fewer number of channels, to thereby render the uppermost channel structure inoperative. Embodiments provide design flexibility while using a fabrication process that is readily adapted to forming a mixture of transistors having differing numbers of channels.

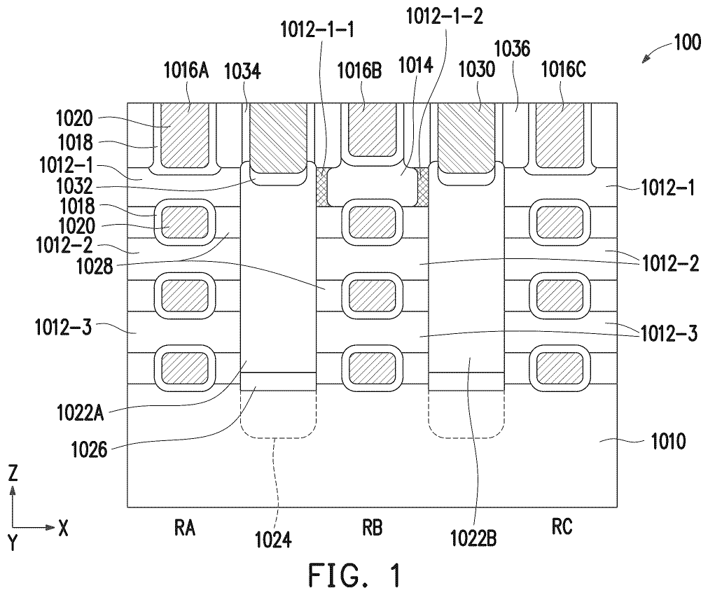

FIG. 1 is a cross-sectional view of a semiconductor device 100 according to some embodiments.

The semiconductor device 100 includes a substrate 1010. Regions RA and RC each have three channel structures 1012-1, 1012-2, and 1012-3 (which may be referred to as a first channel structure 1012-1, a second channel structure 1012-2, and a third channel structure 1012-3). The first channel structure 1012-1 is over the second channel structure 1012-2, and the second channel structure is over the third channel structure 1012-3 such that the channel structures 1012-1, 1012-2, and 1012-3 are arranged in a stack in the Z-axis direction, with the first channel structure 1012-1 being the uppermost channel structure (farthest from the substrate 1010) and the third channel structure being a lowermost channel structure (closest to the substrate 1010). The channel structures may be collectively referred to as channel structures 1012. The channel structures may also be referred to as active regions or OD regions, or parts thereof.

Region RB between the regions RA and RC has the second and third channel structures 1012-2 and 1012-3. In region RB, an insulating structure 1014 is present in a least a portion of a region corresponding to the uppermost channel structure, e.g., the first channel structure 1012-1 in FIG. 1. The insulating structure 1014 at least partially replaces the uppermost channel structure, thus blocking a current path between source/drain regions through the uppermost channel structure and disabling the current-carrying function of the uppermost channel structure in region RB. Disabling the uppermost channel structure helps to provide design flexibility, reduce current flow, reduce energy consumption, and/or reduce capacitance in multi-channel transistors having the disabled channel structure. In some embodiments, the lowermost channel structure, e.g., the third channel structure 1012-3, is maintained as a functional channel or current-carrying channel, and a backside power delivery (BPD) structure is employed.

The semiconductor device 100 is described herein as having a hybrid-channel structure in which at least one transistor has three channel structures and at least one transistor has two channels (a three-channel/two-channel device). However, the number of channel structures is different in other embodiments. In other embodiments the semiconductor device is, for example, an n-channel/n-1 channel device in which n is less than three or more than three, e.g., five or more. As described in further detail below, an n-channel transistor can be directly adjacent to an n-1 channel transistor, n-channel transistors can be arranged in one row and n-1 channel transistors can be arranged in another row, n-channel transistors can form one standard cell and n-1 channel transistors can form another standard cell, and the like.

In some embodiments, the semiconductor device or a region thereof, a standard cell, a circuit, or the like is formed with a same number of channel regions in all rows at all transistor locations, and a subsequent operation or operations are performed to selectively disable the uppermost channel region for one or more transistors. This approach can provide a hybrid-channel semiconductor device with low additional costs, e.g., one additional mask. In some embodiments, the channel structures are semiconductor nanosheets, e.g., sheets of epitaxial silicon, and the semiconductor device is a hybrid nanosheet device. In some embodiments, disabling an uppermost channel structure or nanosheet in one transistor has little or no deleterious effects on an adjacent transistor having an undisabled upper channel structure or nanosheet.

In FIG. 1, the insulating structure 1014 replaces at least a portion of the first channel structure 1012-1 in region RB, thus disabling or inactivating the top or uppermost channel structure of the stack of channel structures in region RB. In some embodiments, the first channel structure 1012-1 is initially formed in region RB and is then partially replaced with the insulating structure 1014. In this case, as shown in FIG. 1, portions 1012-1-1 and 1012-1-2 of the first channel structure 1012-1 in region RB remain adjacent to the insulating structure 1014. In some embodiments, the portions 1012-1-1 and 1012-1-2 of the first channel structure 1012-1 include lightly-doped regions (e.g., LDD regions) of the first channel structure 1012-1. In some embodiments, the portions 1012-1-1 and 1012-1-2 are doped at a concentration less than that of the adjacent source/drain structures. As described below, in other embodiments the first channel structure is completely removed in region RB.

In some embodiments, the substrate 1010 is a semiconductor substrate, such as a bulk semiconductor, or the like, which in some embodiments is doped (e.g., with a p-type or an n-type dopant) and in other embodiments is undoped. In some embodiments, the substrate 1010 includes silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. In some embodiments, the substrate 1010 is a single-layer substrate, a multi-layered substrate, or a gradient substrate.

In some embodiments, the channel structures 1012-1, 1012-2, and 1012-3 are or include epitaxial layers of a semiconductor material such as silicon (Si). In some embodiments, the epitaxial layers of the channel structures 1012-1, 1012-2, and 1012-3 are silicon that is doped with a dopant, e.g., during growth of the epitaxial layers or subsequent to growth of the epitaxial layers. In some embodiments, the channel structures are nanostructures such as nanosheets, nanowires, or the like. In some embodiments, a circuit includes stacked nano-sheets with n-sheet regions and (n-1)-sheet regions. Although some embodiments are described herein as using silicon-based channel structures, e.g., silicon-based nanosheets or epitaxial sheets, in other embodiments the channel structures are implemented using, e.g., carbon-containing nanotubes, graphene-based structures, and the like.

In some embodiments, the insulating structure 1014 includes one or more of Al₂O₃, a nitride such as silicon nitride (Si₃N₄), SiO₂, TiO₂, AlN, BN, SiOC, SiCN, SiOCN, SiO₂:F, a hydrogen silsesquioxane, or the like. In some embodiments, the material of the insulating structure 1014 is porous or includes voids. In some embodiments, the insulating structure 1014 is a dielectric structure. In some embodiments, the insulating structure 1014 includes a dielectric material having a dielectric constant κ greater than 3, e.g., greater than 3.9 (silicon oxide), e.g., 6, 7, 10 , or more than 10. In some embodiments, forming the insulating structure 1014 of higher-κ materials helps to improve electrical properties of the device and/or improve fabrication processes.

Region RA includes a first gate structure 1016A. Region RB includes a second gate structure 1016B. Region RC includes a third gate structure 1016C. The first gate structure 1016A at least partially surrounds each of the first, second, and third channel structures 1012-1, 1012-2, and 1012-3 in region RA. The second gate structure 1016B at least partially surrounds each of the second and third channel structures 1012-2, and 1012-3 in region RB. In some embodiments, the second gate structure 1016B at least partially surrounds the insulating structure 1014 in region RB as well as at least partially surrounding each of the second and third channel structures 1012-2 and 1012-3 in region RB. The third gate structure 1016C at least partially surrounds each of the first, second, and third channel structures 1012-1, 1012-2, and 1012-3 in region RC.

The first, second, and third gate structures 1016A, 1016B, and 1016C each include a gate dielectric layer 1018 and a gate electrode layer 1020. The gate dielectric layer 1018 isolates the gate electrode layer 1020 from the first, second, and third channel structures 1012-1, 1012-2, and 1012-3, and isolates the gate electrode layer 1020 from the insulating structure 1014.

In some embodiments, the gate dielectric layer 1018 is or includes a high-κ dielectric material, where high-κ refers to a material having a dielectric constant greater than that of silicon oxide (about 3.9). In some embodiments, the gate dielectric layer 1018 includes one or more of Gd₂O₅, HfAlO, HfErO, HfGdO, HfLaO, HfO₂, HfTaO, HfTiO, HfYO, HfZrO, La₂O₅, SrTiO, Ta₂O₅, TiO₂, Y₂O₃, ZrO₂, or the like. In some embodiments, the gate dielectric layer 1018 is formed of a different insulating material than an insulating material forming the insulating structure 1014.

In some embodiments, the gate electrode layer 1020 is or includes a conductive material such as polysilicon or a metal. In some embodiments, the gate electrode layer 1020 includes aluminum (Al), tungsten (W), copper (Cu), a combination of two or more thereof, or the like.

In some embodiments, the gate electrode layer 1020 includes one or more work function metal layers and a bulk conductive or fill-metal layer. In some embodiments, the work-function layer includes a TaN layer and a titanium aluminum (TiAl) layer over the TaN layer; a TaN layer, a TiN layer over the TaN layer, and a TiAl layer over the TiN layer, or the like. Other suitable materials for the work-function layer include titanium aluminum nitride (TiAlN), tantalum carbon nitride (TaCN), titanium nitride (TiN), tungsten nitride (WN), tungsten (W), or a combination of two more thereof. The fill-metal layer is formed over the work-function layer and serves as the main conductive portion of the gate structure. In some embodiments, the fill-metal layer includes aluminum, tungsten, copper, cobalt, a combination of two or more thereof, or the like.

In some embodiments, the first, second, and third gate structures 1016A, 1016B, and 1016C are high-κ metal gate (HKMG) structures.

A first source/drain (s/d) structure 1022A is between the first gate structure 1016A and the second gate structure 1016B. A second source/drain structure 1022B is between the second gate structure 1016B and the third gate structure 1016C.

In some embodiments, the first and second source/drain structures 1022A and 1022B are a semiconductor material, e.g., an epitaxial semiconductor material. In some embodiments, the semiconductor material includes one or more of Ge, Si, GaAs, AlGaAs, SiGe, GaAsP, SiP, or the like. In some embodiments, the source/drain structures include a dopant. In some embodiments, epitaxially grown SiGe source/drain structures are doped with boron. In some embodiments, epitaxially grown Si epi source/drain structures are doped with carbon to form Si: C source/drain structures, phosphorous to form Si: P source/drain structures, or both carbon and phosphorous to form SiCP source/drain structures. In some embodiments, the source/drain structures in-situ doped, i.e., during an epitaxial growth process. In some embodiments, the source/drain structures are not in-situ doped, and instead an implantation process is performed to dope the source/drain structures.

In FIG. 1, the source/drain structures 1022A and 1022B each include a liner layer 1024 and a bottom isolation layer 1026 at bottoms of the source/drain structures 1022A and 1022B.

The liner layer 1024 may be referred to as an L0 layer. In some embodiments, the liner layer 1024 includes silicon. The liner layer 1024 is between the bottom isolation layer 1026 and the substrate 1010.

The bottom isolation layer 1026 may be referred to as a flexible bottom insulator or flexible bottom isolation (FBI). In some embodiments, the bottom isolation layer 1026 is or includes silicon nitride.

In FIG. 1, inner spacers 1028 are at sides of the source/drain structures 1022A and 1022B.

In some embodiments, the material forming the inner spacers 1028 is or includes amorphous silicon, or a dielectric material such as silicon oxide, silicon nitride, silicon carbide, silicon oxynitride, SiCN, silicon oxycarbide, SiOCN, a material with a dielectric constant κ<7, or the like.

In FIG. 1, contact structures 1030 are on each of the source/drain structures 1022A and 1022B. The contact structures 1030 may be referred to as metal-to-device or metal-on-diffusion structures (MD structures).

In some embodiments, the contact structures 1030 are or include one or more conductive materials such as a metal, a metal compound, a doped semiconductor, or the like. In some embodiments, the contact structures 1030 include one more metals such as Al, Co, Cu, Ru, W, or the like. In some embodiments, the contact structures 1030 include one or more metal compounds such as AlCu, NiSix, TaN, TiN, TiSix, WTiN, or the like. In some embodiments, the contact structures 1030 include one or more a doped semiconductors such as doped Si, doped SiGe, or the like.

In FIG. 1, silicide layers 1032 are present at the interface of the contact structures 1030 and the source/drain structures 1022A and 1022B. The silicide layers 1032 improve electrical conductivity between the contact structures 1030 and the source/drain structures 1022A and 1022B.

In FIG. 1, contact etch stop layers (CESL) 1034 are present at sides of the contact structures 1030.

In some embodiments, the contact etch stop layers 1034 are or include a material, e.g., an insulating material, having a different etch selectivity from adjacent layers or components. In some embodiments, contact etch stop layers 1034 are or include a nitrogen containing material, a silicon containing material, a carbon containing material, or the like. Examples of the materials include silicon nitride, silicon carbon nitride, carbon nitride, silicon oxynitride, silicon carbon oxide, and the like.

In FIG. 1, spacers 1036 are present between upper portions of the first gate structure 1016A and the first source/drain structure 1022A, between upper portions of the first source/drain structure 1022A and the second gate structure 1016B, between upper portions of the second gate structure 1016B and the second source/drain structure 1022B, and between upper portions of the second source/drain structure 1022B and the third gate structure 1016C. The contact etch stop layers 1034 are interposed between the spacers 1036 and the contact structures 1030.

In some embodiments, the spacers 1036 are or include one or more of SiN, SiCN, SiOC, SiOCN, or the like.

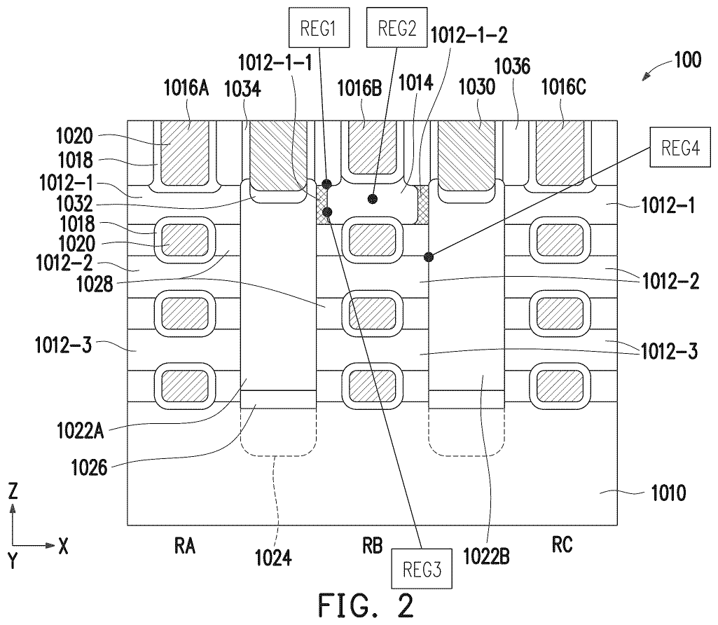

FIG. 2 is a cross-sectional view showing capacitance effects in the semiconductor device 100 according to some embodiments.

In FIG. 2, a first region REG1 is an upper region of the second gate structure 1016B where a spacer 1036 is proximate to the insulating structure 1014 and the portion 1012-1-1 of the first channel structure 1012-1 in region RB.

In the first region REG1, the upper portion of the second gate structure 1016B over the insulating structure 1014 is higher relative to where it would be over the first channel structure 1012-1 in the absence of the insulating structure 1014. Thus, in some embodiments C_{co} (a contact capacitance between source/drain contact structures 1030 and the second gate structure 1016B) is reduced slightly. Also, in some embodiments C_{of_sp} (an outer fringe capacitance component at the spacers 1036) is reduced slightly. However, in some embodiments an R_{G} (gate resistance) is increased, which is a trade-off.

In FIG. 2, a second region REG2 is a region where the insulating structure 1014 is located.

In the second region REG2, the combined effect of Cₒₓ (gate dielectric capacitance or gate oxide capacitance) and Cᵢₙᵥ (inversion capacitance) (Cₒₓ ∥Cᵢₙᵥ) is reduced, e.g., by about ⅓, due to removing some or all of the first channel structure 1012-1 (e.g., one nanosheet) of the first, second, and third channel structures 1012-1, 1012-2, and 1012-3 (e.g., three nanosheets).

In FIG. 2, a third region REG3 is a region where the insulating structure 1014 is proximate to portion 1012-1-1 of the first channel structure 1012-1 in region RB.

In some embodiments, in the third region REG3, Cₒᵥ (an overlay capacitance between the lightly doped portions 1012-1-1 and 1012-1-2 and the second gate structure 1016B) is reduced, e.g., by less than ⅓, in the case that the LDD regions are partially removed. Also, in some embodiments C_{if} (an inner fringe capacitance between the active region and the gate structure 1016B) is reduced, e.g., by less than ⅓, in the case that the LDD regions are partially removed.

In FIG. 2, a fourth region REG4 is a region where an inner spacer 1028 is proximate to the source/drain structure 1022B and the second channel structure 1012-2.

In the fourth region REG4, C_{of_insp} (an outer fringe capacitance across the inner spacers 1028) is unchanged in some embodiments as compared to a gate structure in which the first channel structure 1012-1 is not removed (i.e., is functional).

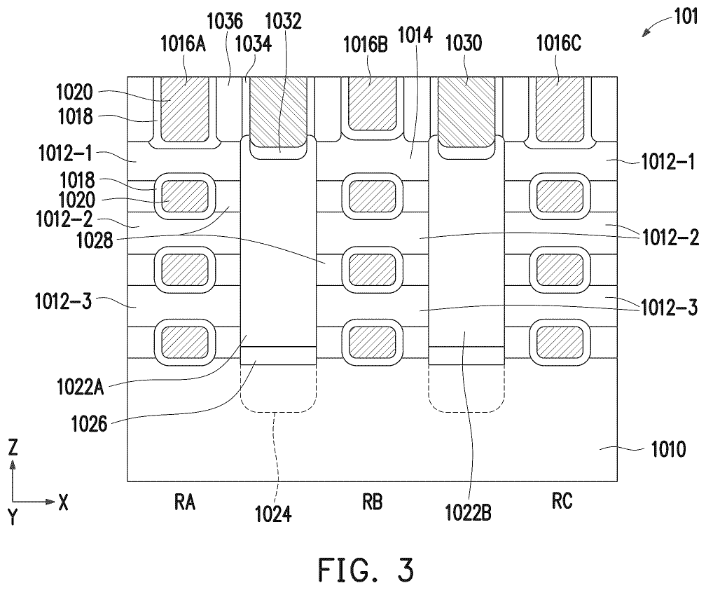

FIG. 3 is a cross-sectional view of a semiconductor device 101 according to some embodiments.

The semiconductor device 101 in FIG. 3 is the same as the semiconductor device 100 in FIG. 1 except that, in the semiconductor device 101, the insulating structure 1014 fully occupies a region between the source/drain structures 1022A and 1022B. In some embodiments, the first channel structure 1012-1 is completely removed between the source/drain structures 1022A and 1022B in region RB such that the portions 1012-1-1 and 1012-1-2 are not present. For example, the lightly-doped regions (e.g., LDD regions) of the first channel structure 1012-1 are replaced with the insulating structure 1014 in some embodiments. In some embodiments, the insulating structure 1014 contacts sidewalls of the source/drain structures 1022A and 1022B.

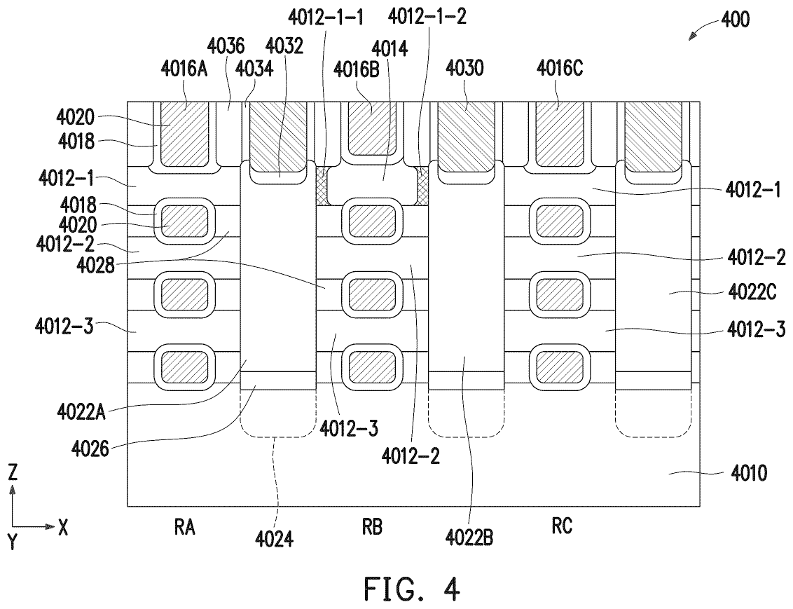

FIG. 4 is a cross-sectional view of a semiconductor device 400 according to some embodiments.

Elements of semiconductor device 400 having a similar structure and function as elements of semiconductor device 100 in the description of FIG. 1 have a same identifying numeral, incremented by 1000, unless stated otherwise or otherwise apparent.

In FIG. 4, the semiconductor device 400 has two transistors having a shared source/drain region, one of the transistors having two channel structures and the other of the transistors having three channel structures. The uppermost channel structure in one of the transistors is deactivated. The deactivation of the uppermost channel structure can be done on a transistor-by-transistor basis, including for adjacent transistors in a same row.

The semiconductor device 400 includes a substrate 4010. On the substrate 4010, regions RA and RC each have three channel structures 4012-1, 4012-2, and 4012-3 (which may be referred to as a first channel structure 4012-1, a second channel structure 4012-2, and a third channel structure 4012-3). The first channel structure 4012-1 is over the second channel structure 4012-2, and the second channel structure is over the third channel structure 4012-3 such that the channel structures 4012-1, 4012-2, and 4012-3 are arranged in a stack in the Z-axis direction, with the first channel structure 4012-1 being the uppermost channel structure (farthest from the substrate 4010) and the third channel structure being a lowermost channel structure (closest to the substrate 4010). Region RB between the regions RA and RC has the second and third channel structures 4012-2 and 4012-3. In region RB, an insulating structure 4014 is present in a least a portion of a region corresponding to the first channel structure 4012-1. The insulating structure 4014 replaces at least a portion of the first channel structure 4012-1 in region RB, thus disabling or inactivating the top or uppermost channel structure of the stack of channel structures in region RB.

In some embodiments, the first channel structure 4012-1 is initially formed in region RB and is then partially replaced with the insulating structure 4014. In this case, as shown in FIG. 4, portions 4012-1-1 and 4012-1-2 of the first channel structure 4012-1 in region RB remain adjacent to the insulating structure 4014. In some embodiments, portions 4012-1-1 and 4012-1-2 of the first channel structure 4012-1 include lightly-doped regions (e.g., LDD regions) of the first channel structure 4012-1.

In other embodiments, the first channel structure 4012-1 is entirely replaced with the insulating structure 4014. In this case, the portions 4012-1-1 and 4012-1-2 are not present, and the insulating structure 4014 occupies the regions corresponding to the portions 4012-1-1 and 4012-1-2. This is described in further detail below.

In some embodiments, the substrate 4010 is a semiconductor substrate, such as a bulk semiconductor, or the like, which in some embodiments is doped (e.g., with a p-type or an n-type dopant) and in other embodiments is undoped. In some embodiments, the substrate 4010 includes silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. In some embodiments, the substrate 4010 is a single-layer substrate, a multi-layered substrate, or a gradient substrate.

In some embodiments, the channel structures 4012-1, 4012-2, and 4012-3 are or include epitaxial layers of silicon (Si). In some embodiments, the epitaxial layers of the channel structures 4012-1, 4012-2, and 4012-3 are silicon that is doped with a dopant, e.g., during growth of the epitaxial layers or subsequent to growth of the epitaxial layers. In some embodiments, the channel structures are nanostructures such as nanosheets, nanowires, or the like. Although some embodiments are described herein as using silicon-based channel structures, in other embodiments the channel structures are implemented using, e.g., carbon-containing nanotubes, graphene-based structures, and the like.

In some embodiments, the insulating structure 4014 is or includes one or more of Al₂O₃ a nitride such as silicon nitride (Si₃N₄), SiO₂, TiO₂, AlN, BN, SiOC, SiCN, SiOCN, SiO₂:F, a hydrogen silsesquioxane, or the like. In some embodiments, the material of the insulating structure 4014 is porous or includes voids. In some embodiments, the insulating structure 4014 is a dielectric structure. In some embodiments, the insulating structure includes a dielectric material having a dielectric constant κ greater than 3, e.g., greater than 3.9, e.g., 6, 7, 10, or more than 10. In some embodiments, forming the insulating structure 4014 of higher-κ materials helps to improve electrical properties of the device and/or improve fabrication processes.

Region RA includes a first gate structure 4016A. Region RB includes a second gate structure 4016B. Region RC includes a third gate structure 4016C. The first gate structure 4016A at least partially surrounds each of the first, second, and third channel structures 4012-1, 4012-2, and 4012-3 in region RA. The second gate structure 4016B at least partially surrounds each of the second and third channel structures 4012-2, and 4012-3 in region RB. In some embodiments, the second gate structure 4016B at least partially surrounds the insulating structure 4014 in region RB as well as at least partially surrounds each of the second and third channel structures 4012-2, and 4012-3 in region RB. The third gate structure 4016C at least partially surrounds each of the first, second, and third channel structures 4012-1, 4012-2, and 4012-3 in region RC.

The first, second, and third gate structures 4016A, 4016B, and 4016C each include a gate dielectric layer 4018 and a gate electrode layer 4020. The gate dielectric layer 4018 isolates the gate electrode layer 4020 from the channel structures 4012-1, 4012-2, and 4012-3, and isolates the gate electrode layer 4020 from the insulating structure 4014.

In some embodiments, the gate dielectric layer 4018 is or includes a high-κ dielectric material, where high-κ refers to a material having a dielectric constant greater than that of silicon oxide, which is about 3.9. In some embodiments, the gate dielectric layer 4018 includes one or more of Gd₂O₅, HfAlO, HfErO, HfGdO, HfLaO, HfO₂, HfTaO, HfTiO, HfYO, HfZrO, La₂O₅, SrTiO, Ta₂O₅, TiO₂, Y₂O₃, ZrO₂, or the like.

In some embodiments, the gate electrode layer 4020 is or includes a conductive material such as polysilicon or a metal. In some embodiments, the gate electrode layer 4020 includes aluminum (Al), tungsten (W), copper (Cu), or a combination of two or more thereof.

In some embodiments, the gate electrode layer 4020 is or includes one or more work function metal layers and a bulk conductive or fill-metal layer. In some embodiments, the work-function layer includes a TaN layer and a titanium aluminum (TiAl) layer over the TaN layer; a TaN layer, a TiN layer over the TaN layer, and a TiAl layer over the TiN layer, or the like. Other suitable materials for the work-function layer include titanium aluminum nitride (TiAlN), tantalum carbon nitride (TaCN), titanium nitride (TiN), tungsten nitride (WN), tungsten (W), or a combination of two more thereof. The fill-metal layer is formed over the work-function layer and serves as the main conductive portion of the gate structure. In some embodiments, the fill-metal layer includes aluminum, tungsten, copper, cobalt, or a combination of two or more thereof.

In some embodiments, the first, second, and third gate structures 4016A, 4016B, and 4016C are high-κ metal gate (HKMG) structures.

A source/drain (s/d) structure 4022A is between the first gate structure 4016A and the second gate structure 4016B. A source/drain structure 4022B is between the second gate structure 4016B and the third gate structure 4016C. A source/drain structure 4022C is on an opposite side of the third gate structure 4016C from the source/drain structure 4022B. A first transistor having two channel structures includes the source/drain structure 4022A, the second gate structure 4016B, and the source/drain structure 4022B. A second transistor having three channel structures includes the source/drain structure 4022B, the third gate structure 4016C, and the source/drain structure 4022C.

In some embodiments, the source/drain structures 4022A and 4022B are or include a semiconductor material, e.g., an epitaxial semiconductor material. In some embodiments, the semiconductor material includes one or more of Ge, Si, GaAs, AlGaAs, SiGe, GaAsP, SiP, or the like. In some embodiments, the source/drain structures include a dopant. In some embodiments, epitaxially grown SiGe source/drain structures are doped with boron. In some embodiments, epitaxially grown Si epi source/drain structures are doped with carbon to form Si: C source/drain structures, phosphorous to form Si: P source/drain structures, or both carbon and phosphorous to form SiCP source/drain structures. In some embodiments, the source/drain structures in-situ doped, i.e., during an epitaxial growth process. In some embodiments, the source/drain structures are not in-situ doped, and instead an implantation process is performed to dope the source/drain structures.

In FIG. 4, the source/drain structures 4022A and 4022B each include a liner layer 4024 and a bottom isolation layer 4026 at bottoms of the source/drain structures 4022A and 4022B.

The liner layer 4024 may be referred to as an L0 layer. In some embodiments, the liner layer 4024 is or includes silicon. The liner layer 4024 is between the bottom isolation layer 4026 and the substrate 4010.

The bottom isolation layer 4026 may be referred to as a flexible bottom insulator or flexible bottom isolation (FBI). In some embodiments, the bottom isolation layer 4026 is or includes silicon nitride.

In FIG. 4, inner spacers 4028 are at sides of the source/drain structures 4022A and 4022B.

In some embodiments, the material forming the inner spacers 4028 includes amorphous silicon, or a dielectric material such as silicon oxide, silicon nitride, silicon carbide, silicon oxynitride, SiCN, silicon oxycarbide, SiOCN, a material with a dielectric constant κ<7, or the like.

In FIG. 4, contact structures 4030 are on each of the source/drain structures 4022A and 4022B. The contact structures 4030 may be referred to as metal-to-device or metal-on-diffusion structures (MD structures).

In some embodiments, the contact structures 4030 include one or more conductive materials such as a metal, a metal compound, a doped semiconductor, or the like. In some embodiments, the contact structures 4030 include one more metals such as Al, Co, Cu, Ru, W, or the like. In some embodiments, the contact structures 4030 include one or more metal compounds such as AlCu, NiSix, TaN, TiN, TiSix, WTiN, or the like. In some embodiments, the contact structures 4030 include one or more a doped semiconductors such as doped Si, doped SiGe, or the like.

In FIG. 4, silicide layers 4032 are present at the interface of the contact structures 4030 and the source/drain structures 4022A and 4022B. The silicide layers 4032 improve electrical conductivity between the contact structures 4030 and the source/drain structures 4022A and 4022B.

In FIG. 4, contact etch stop layers (CESL) 4034 are present at sides of the contact structures 4030.

In some embodiments, the contact etch stop layers 4034 are or include a material, e.g., an insulating material, having a different etch selectivity from adjacent layers or components. In some embodiments, contact etch stop layers 4034 are or include a nitrogen containing material, a silicon containing material, a carbon containing material, or the like. Examples of the materials include silicon nitride, silicon carbon nitride, carbon nitride, silicon oxynitride, silicon carbon oxide, and the like.

In FIG. 4, spacers 4036 are present between upper portions of the first gate structure 4016A and the source/drain structure 4022A, between upper portions of the source/drain structure 4022A and the second gate structure 4016B, between upper portions of the second gate structure 4016B and the source/drain structure 4022B, and between upper portions of the source/drain structure 4022B and the third gate structure 4016C. The contact etch stop layers 4034 are interposed between the spacers 4036 and the contact structures 4030.

In some embodiments, the spacers 4036 are or include one or more of SiN, SiCN, SiOC, SiOCN, or the like.

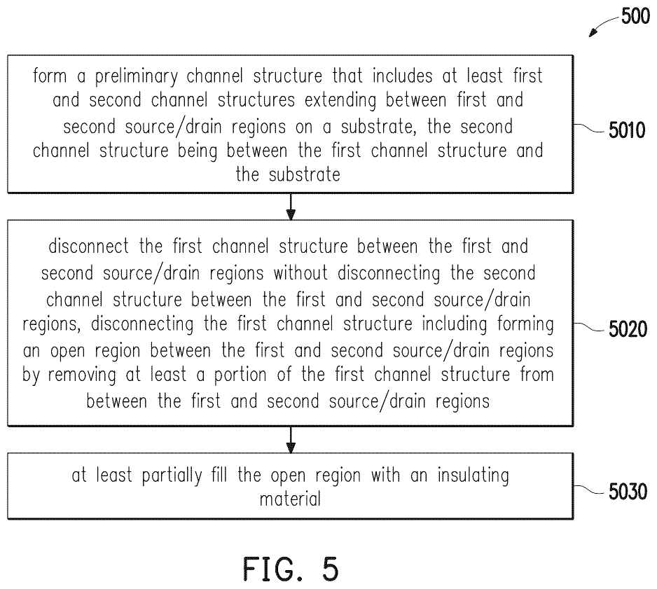

FIG. 5 is a flowchart of a method 500 of fabricating a semiconductor device according to some embodiments.

Referring to FIG. 5, the method 500 includes operations 5010, 5020, and 5030.

Operation 5010 includes forming an intermediate device structure in which a preliminary channel structure includes at least first and second channel structures extending between first and second source/drain regions on a substrate, the second channel structure being between the first channel structure and the substrate. In some embodiments, the number of channel structures is greater than two, e.g., three, four, five, or more than five. In such embodiments, the first channel structure is an uppermost channel structure among the preliminary channel structures, and the second, third, fourth, fifth, etc., channel structures are between the first channel structure and the substrate, i.e., are under the first channel structure.

In some embodiments, the channel structures are epitaxial channel layers of a semiconductor material, which are alternately stacked with dummy (sacrificial) layers. In some embodiments, forming the preliminary channel structure includes forming epitaxial layers of a first composition and epitaxial layers of a second composition that interpose the layers of the first composition, where the epitaxial layers of the first composition form the dummy layers, and the epitaxial layers of the second composition form the semiconductor channel layers. In some embodiments, the epitaxial layers of the first composition are SiGe and the epitaxial layers of the second composition are silicon (Si). In some embodiments, the epitaxial layers of the second composition are silicon that is doped with a dopant, e.g., during growth of the epitaxial layers or subsequent to growth of the epitaxial layers.

In some embodiments, the epitaxial layers of the second composition, or portions thereof, form a channel region of a gate all-around (GAA) transistor. In some embodiments, the semiconductor channel layers are or include nanosheet channel(s), nanowire channel(s), bar-shaped channel(s), and/or other suitable channel configurations. In some embodiments, the semiconductor channel layers are also used to form portions of the source/drain features of the GAA transistor or LDD regions. The number of epitaxial layers can be varied depending on the desired number of semiconductor channel layers for the GAA transistor.

In some embodiments, the epitaxial layers of the first composition each have a thickness of about 5 nanometers (nm) to about 15 nm. In some embodiments, the epitaxial layers of the second composition each have a thickness of about 5 nm to about 15 nm. In some embodiments, the epitaxial layer of the second composition is thinner than the epitaxial layers of the first composition. The epitaxial layers of the second composition serve as channel region(s), e.g., for a GAA transistor, and the thicknesses of the epitaxial layers of the second composition are chosen based on, e.g., one or more of device performance considerations, device fabrication considerations, or the like. The epitaxial layers of the first composition define a gap or spacing (i.e., a vertical distance) between adjacent channel region(s) in the transistor. The thicknesses of the epitaxial layers of the first composition are chosen based on, e.g., one or more of device performance considerations, device fabrication considerations, or the like.

The intermediate device structure further includes a dummy (sacrificial) gate stack, which is subsequently removed and replaced by a final (functional) gate stack at a subsequent processing stage. This may be referred to as a replacement gate approach. In some embodiments the dummy gate stack is replaced with a gate dielectric layer, e.g., a high-κ gate dielectric layer (HK), and metal gate electrode (MG) (HKMG structure). In other embodiments, a gate-first approach is used instead of a replacement gate approach.

In some embodiments, the dummy gate stack includes a dielectric layer that is covered by or surrounded by a dummy electrode layer. In some embodiments, the dummy gate stack also includes one or more of a hard mask layer, a contact etch stop layer (CESL), or the like. In some embodiments, the dielectric layer includes one or more of silicon oxide, silicon nitride, a high-κ dielectric material, or the like. In some embodiments, the dummy electrode layer includes polycrystalline silicon (polysilicon).

In some embodiments, after formation of the dummy gate stack, one or more spacer layers are conformally deposited, e.g., over the dummy gate stack and on sidewalls of the dummy gate stack. In some embodiments, the spacer layers have a total thickness of about 2 nm to about 10 nm. In some embodiments, the spacer layers include one or more of a dielectric material such as silicon oxide, silicon nitride, silicon carbide, silicon oxynitride, SiCN, silicon oxycarbide, SiOCN, a material having a dielectric constant κ<7, or the like. In some embodiments, the spacer layers are formed by conformally depositing a dielectric material using a process such as a CVD process, a subatmospheric CVD (SACVD) process, a flowable CVD process, an ALD process, a PVD process, or the like.

In some embodiments, source/drain structures are formed after the formation of the dummy gate stack. In some embodiments, an etch process is performed to form trenches for the source/drain structures, the trenches being adjacent to the dummy gate stack and expose ends and/or lateral surfaces of the epitaxial layers. In some embodiments, the source/drain etch process includes one or more of a dry etching process, a wet etching process, or the like.

In some embodiments, after forming the trenches, a dummy layer recess process is performed to laterally etch the dummy layers and form recesses along sidewalls of the trenches. In some embodiments, the dummy layer recess process is performed using one or more of a dry etching process, a wet etching process, or the like

In some embodiments, as a result of the dummy layer recess process, the recessed dummy layers define concave profiles along opposing lateral surfaces of the dummy layers. During a later stage of processing, as discussed below, the dummy layers will be removed and replaced by a portion of a gate structure (e.g., a metal gate structure) such that the replacement gate structure at least partially defines the concave profile. In various examples, the replacement gate structure will interface with an inner spacer, as also described in more detail below.

In some embodiments, after the dummy layer recess process, an inner spacer material is deposited within the trenches formed by the source/drain etch process and within the recesses formed by the dummy layer recess process. In some embodiments, the inner spacer material includes amorphous silicon, or a dielectric material such as silicon oxide, silicon nitride, silicon carbide, silicon oxynitride, SiCN, silicon oxycarbide, SiOCN, a material with a dielectric constant κ<7, or the like.

In some embodiments, after deposition of the inner spacer material, an inner spacer etch-back process is performed to etch the inner spacer material from over the device and along sidewalls of the trenches formed by the source/drain etch process, while the inner spacer material remains disposed within the recesses formed by the dummy layer recess process, thereby providing inner spacers for the device. The inner spacers are formed in contact with the recessed dummy layers having the concave profiles such that the inner spacers define a complementary convex sidewall profile that interfaces the concave profile. In some embodiments, the inner spacers extend beneath the spacer layer (formed on sidewalls of the gate stacks) while being disposed adjacent to subsequently-formed source/drain structures. In some embodiments, the inner spacers extend at least partially beneath the gate stacks.

After formation of the inner spacers, source/drain structures are formed adjacent to and on either side of the dummy gate stack. In some embodiments, the source/drain structures are formed within the trenches formed by the source/drain etch process, and in contact with the adjacent inner spacers and the semiconductor channel layers of the device.

In some embodiments, the source/drain structures are formed by epitaxially growing a semiconductor material layer. In some embodiments, the semiconductor material layer grown to form the source/drain structures includes one or more of Ge, Si, GaAs, AlGaAs, SiGe, GaAsP, SiP, or the like. In some embodiments, the source/drain structures are in-situ doped during the epitaxial growth process. In some embodiments, epitaxially grown SiGe source/drain structures are doped with boron. In some embodiments, epitaxially grown Si epi source/drain structures are doped with carbon to form Si: C source/drain structures, phosphorous to form Si: P source/drain structures, or both carbon and phosphorous to form SiCP source/drain structures. In some embodiments, the source/drain structures are not in-situ doped, and instead an implantation process is performed to dope the source/drain structures.

In some embodiments, after forming the source/drain structures, a contact etch stop layer (CESL) is formed. In some examples, the CESL includes one or more of a silicon nitride layer, a silicon oxide layer, a silicon oxynitride layer, or the like.

In some embodiments, an inter-layer dielectric (ILD) layer is formed over the CESL. In some embodiments, the ILD layer includes one or more of tetraethylorthosilicate (TEOS) oxide, an un-doped silicate glass, a doped silicon oxide such as borophosphosilicate glass (BPSG), fluorosilicate glass (FSG), phosphosilicate glass (PSG), boron doped silicon glass (BSG), or the like.

In some embodiments, after formation of the CESL and the ILD layer, a chemical mechanical polishing (CMP) process is performed to remove portions of the ILD layer and the CESL overlying the gate stacks, as well as the hard mask layers overlying the gate stacks, to planarize a top surface of the device and expose a top surface of the electrode layer.

Operation 5020 includes disconnecting the first channel structure (uppermost channel structure) between the first and second source/drain regions without disconnecting the second channel structure (lower channel structure) between the first and second source/drain regions. Disconnecting the first channel structure includes forming an open region between the first and second source/drain regions by removing at least a portion of the first channel structure from between the first and second source/drain regions.

In some embodiments, disconnecting the first channel structure between the first and second source/drain regions includes removing a portion of the first channel structure, while allowing a first portion of the first channel structure to remain adjacent to a sidewall of the first source/drain region, and allowing a second portion of the first channel region to remain adjacent to a sidewall of the second source/drain region. In some embodiments, the first and second portions represent at least some of lightly-doped regions, which may be referred to as lightly-doped drain (LDD) regions. In some embodiments, the LDD regions are doped with a same dopant as the adjacent source/drain region but at a lower concentration of the dopant than in the adjacent source/drain region. In some embodiments, the LDD regions include a dopant that is diffused from the adjacent source/drain region. Allowing portions of the first channel structure to remain adjacent to the sidewalls of the source/drain structures can help minimize unwanted removal or etching of the source/drain regions.

In some embodiments, disconnecting the first channel structure between the first and second source/drain regions includes entirely removing the first channel structure, from a sidewall of the first source/drain region to a sidewall of the second source/drain region. Entirely removing the first channel structure in this way can help to beneficially reduce capacitance of the transistor structure.

In operation 5030, the open region that disconnects the first channel structure is at least partially filled with an insulating material. In some embodiments, the insulating material includes one or more of Al₂O₃, a nitride such as silicon nitride (Si₃N₄), SiO₂, TiO₂, AlN, BN, SiOC, SiCN, SiOCN, SiO₂:F, a hydrogen silsesquioxane, or the like. In some embodiments, the insulating material is formed to be porous or include voids. In some embodiments, the insulating material is a dielectric material. In some embodiments, the insulating material includes a dielectric material having a dielectric constant κ greater than 3, e.g., greater than 3.9 (silicon oxide), e.g., 6, 7, 10, or more than 10. In some embodiments, forming the insulating material of higher-κ materials helps to improve electrical properties of the device and/or improve fabrication processes.

In another approach, a channel structure can be deactivated or inactivated by, e.g., oxidizing a portion of the channel structure, e.g., an upper half of the channel structure. In the other approach, the deactivated portion of the channel structure is thus an oxide of the material forming the channel structure. On the other hand, according to some embodiments, a dielectric material that is filled in the open region in operation 5030 has a dielectric constant that is greater than a dielectric constant of the oxide of the material forming the channel region. Also, in the other approach, oxidizing the channel structure produces a structure having dimensions that generally correspond to the unoxidized channel structure. On the other hand, according to some embodiments, the insulating material that is filled in the open region has a dimension that is greater than that of the (removed) channel structure. Even in the case that an oxide of the channel structure increases in thickness relative to the unoxidized channel structure, in some embodiments the insulating material that is filled in the open region nevertheless is formed to have a greater thickness than the oxide of the channel structure. In some embodiments, the insulating material that is filled in the open region extends higher (i.e., relative to the substrate) than the previously-present channel structure did and extends higher than would an oxide of the previously-present channel structure.

FIGS. 6A, 6B, 6C, 6D-1, and 6D-2 are cross-sectional views of stages in a method 600 of fabricating a semiconductor device according to some embodiments.

FIGS. 6A, 6B, 6C, 6D-1, and 6D-2 include: (i) cross-sections in an X-Z plane showing adjacent gate structures; (ii) first cross-sections ‘A’ in a Y-Z plane showing formation of a first gate structure having two functional channels, and (iii) second cross-sections ‘B’ in the Y-Z plane showing formation of a second gate structure having three functional channels.

FIGS. 6A, 6B, 6C, 6D-1, and 6D-2 show sequential stages 600A, 600B, 600C, 600D, 600E, 600F, 600G, 600H, and 600I. Additional fabrication operations before stage 600A and/or after stage 600I can also be performed. Additional fabrication operations between any of stages 600A, 600B, 600C, 600D, 600E, 600F, 600G, 600H, and 600I can also be performed. Further, one or more of stages 600A, 600B, 600C, 600D, 600E, 600F, 600G, 600H, or 600I are omitted or replaced in some embodiments.

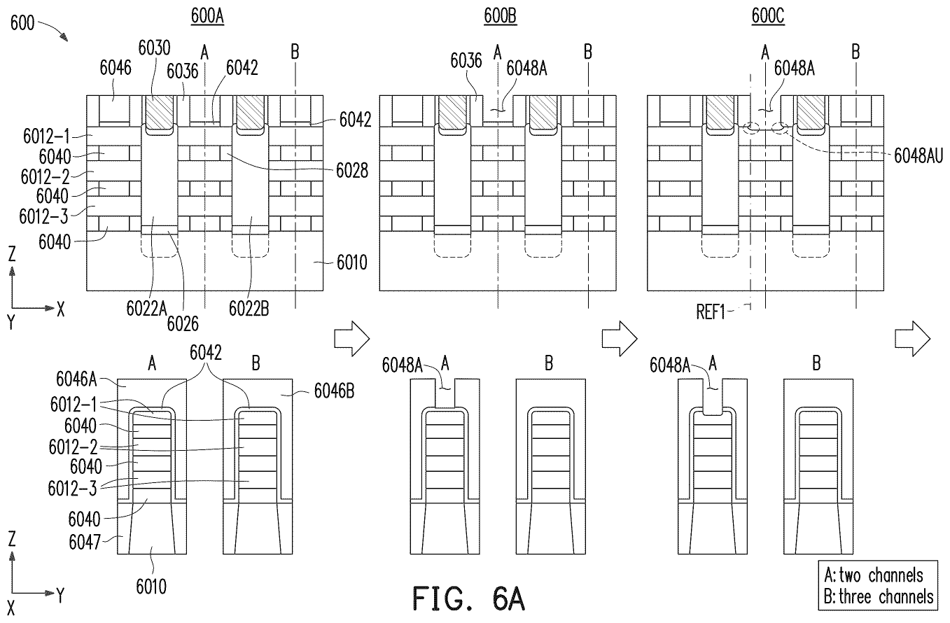

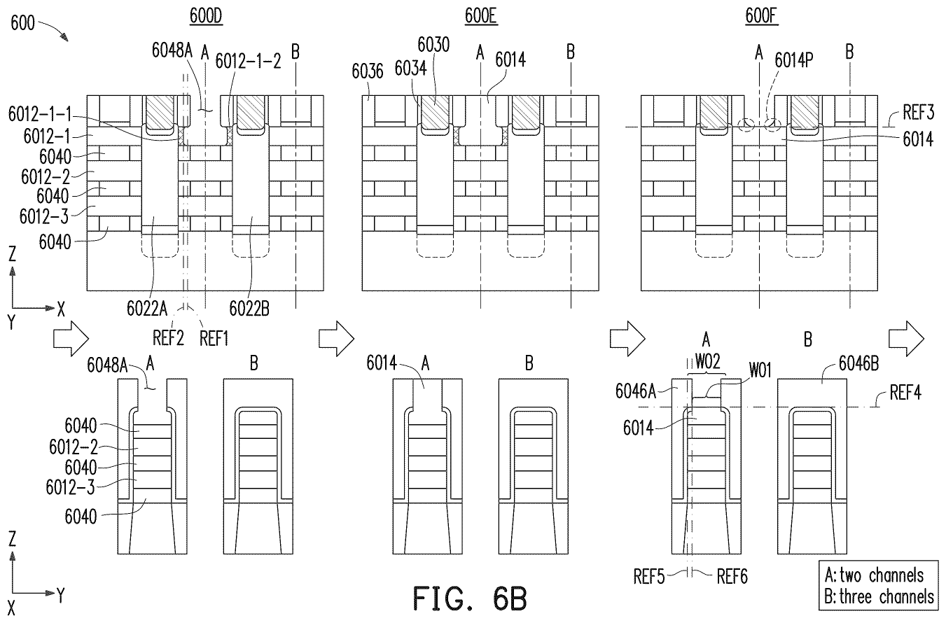

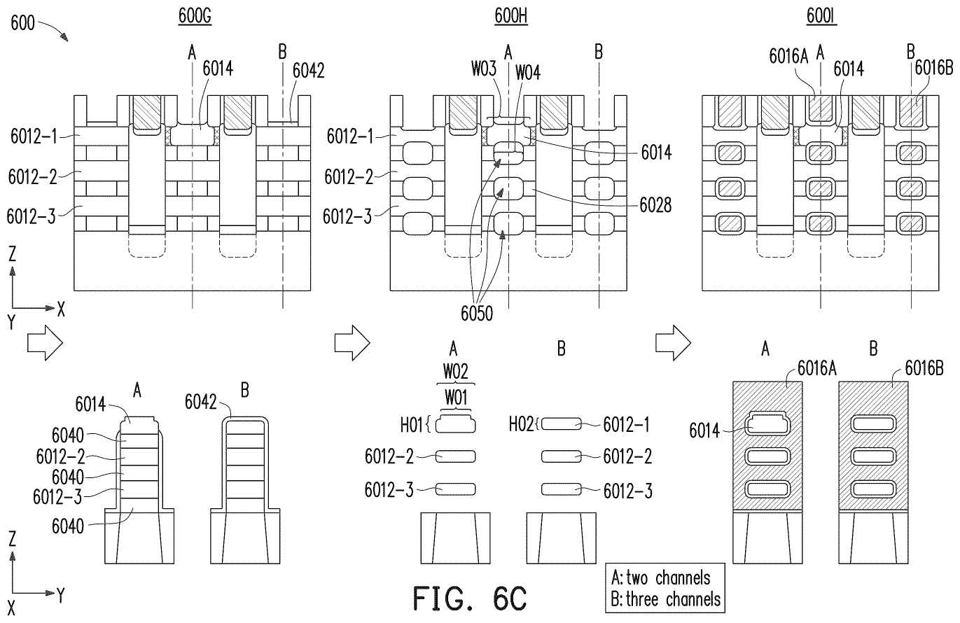

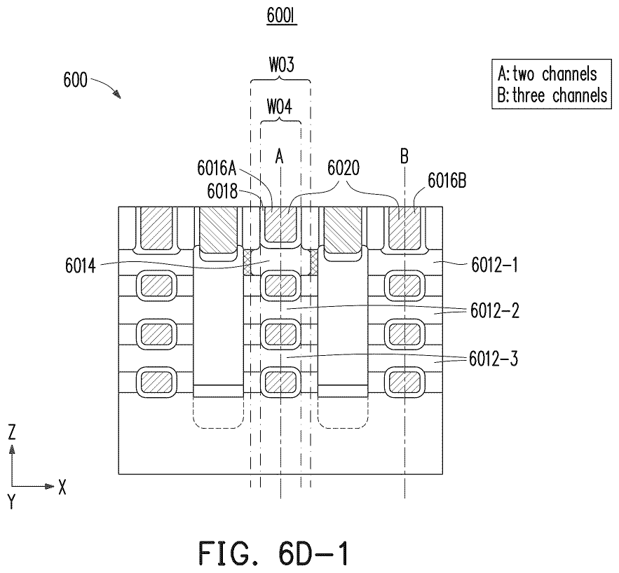

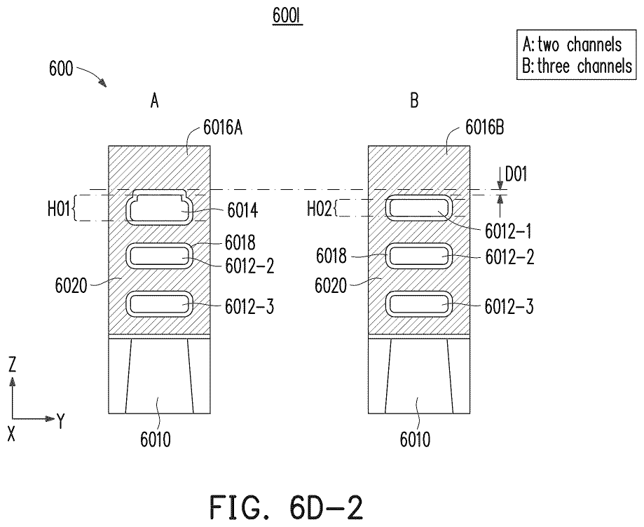

In stage 600A in FIG. 6A, an intermediate device structure includes a first channel structure 6012-1, a second channel structure 6012-2, and a third channel structure 6012-3, with the first channel structure 6012-1 being the uppermost channel structure (farthest from substrate 6010) and the third channel structure being a lowermost channel structure (closest to the substrate 6010) (the first, second, and third channel structures 6012-1~6012-3 may be referred to collectively as channel structures 6012). Source/drain structures 6022A and 6022B electrically contact the channel structures 6012-1, 6012-2, and 6012-3. Contact structures 6030 are on each of the source/drain structures 6022A and 6022B. Inner spacers 6028 are at sides of the source/drain structures 6022A and 6022B. A bottom isolation layer 6026 is present at bottoms of the source/drain structures 6022A and 6022B. Interleaved with the channel structures 6012-1~6012-3 are sacrificial layers 6040. In some embodiments, the sacrificial layers 6040 are an oxide. In some embodiments, the channel structures are formed alternately with sacrificial layers, e.g., sacrificial layers of SiGe, and then the sacrificial layers of SiGe are replaced with an oxide, e.g., an oxide of silicon or an oxide of SiGe. In other embodiments, the intermediate device structure in stage 600A retains the SiGe sacrificial layers (i.e., has SiGe sacrificial layers instead of oxide sacrificial layers). However, the use of oxide sacrificial layers (e.g., replacing SiGe with an oxide) can help reduce or avoid the possibility of germanium diffusing into the channel structures 6012-1, 6012-2, and 6012-3 during process operations, and can provide a greater etch selectivity, e.g., with respect to the interleaved channel structures 6012-1, 6012-2, and 6012-3.

In stage 600A, the intermediate device structure further includes a dummy layer 6042 that covers tops and sides of the channel structures 6012-1, 6012-2, and 6012-3 and the sacrificial layers 6040. In some embodiments, the dummy layer 6042 is or includes an oxide, e.g., silicon oxide.

In stage 600A, the intermediate device structure further includes first and second dummy gate structures 6046A and 6046B (collectively, dummy gate structures 6046) over the dummy layer 6042. The first dummy gate structure 6046A corresponds to the first cross-section ‘A’ and the first gate structure having two functional channels. The second dummy gate structure 6046B corresponds to the second cross-section ‘B’ and the second gate structure having three functional channels. In some embodiments, the dummy gate structures 6046 cover the interleaved stacks of the channel structures 6012-1, 6012-2, and 6012-3 and the sacrificial layers 6040, and the dummy layer 6042 thereon. The dummy gate structures 6046 occupy, at least in part, spaces that will be replaced with functional gates in later operations, e.g., in a replacement gate process. In some embodiments, the dummy gate structures 6046 are polysilicon.

FIG. 6A also shows, in the first cross-sections ‘A’ and the second cross-sections ‘B’, isolation regions 6047 in substrate 6010. In some embodiments, the isolation regions 6047 are shallow trench isolation regions (STI regions).

One or more aspects of operation 5010 of method 500 described above are usable to fabricate one or more features of the intermediate device structure in stage 600A

In stage 600B, an opening 6048A is formed in an upper surface of the first dummy gate structure 6046A (see cross-section ‘A’ in stage 600B). In some embodiments, forming the opening 6048A includes depositing a photoresist layer (not shown in FIG. 6A), patterning the photoresist layer to form an opening over the photoresist layer over the first dummy gate structure 6046A, and etching an upper surface of the first dummy gate structure 6046A through the opening in the photoresist layer to form the opening 6048A in the upper surface of the first dummy gate structure 6046A. In some embodiments, the first dummy gate structure 6046A is polysilicon, the dummy layer 6042 is silicon oxide, the etching operation is selective towards polysilicon, and etching is continued until the opening 6048A exposes the silicon oxide of the dummy layer 6042. Examples of the etching operation for etching the upper surface of the first dummy gate structure 6046A and forming the opening 6048A include an anisotropic etching operation and an isotropic etching operation. In some embodiments, the etching operation is a dry etching operation that stops on the dummy layer 6042.

In some embodiments, the etching operation is selective towards the material of first dummy gate structure 6046A relative to a material of spacers 6036 that are present at sides of the upper portion of the first dummy gate structure 6046A, and the etching operation does not significantly remove the spacers 6036. In other embodiments, a portion of the spacers 6036 is removed such that the spacers 6036 are reduced in thickness in the Y-axis direction by the etching operation. In this case, an upper portion of an insulating structure (see 6014, below) is formed to be wider than the (removed) upper portion of initial dummy gate structure 6046A in some embodiments.

In stage 600C, the dummy layer 6042 is etched to be removed from the bottom of the opening 6048A to expose the first channel structure 6012-1 of the first dummy gate structure 6046A.

Examples of the etching operation for etching the dummy layer 6042 include an anisotropic etching operation and an isotropic etching operation.

In some embodiments, the etching operation that removes the dummy layer 6042 is selective towards the material of the dummy layer 6042 relative to the underlying first channel structure 6012-1 such that the etching operation does not significantly remove the first channel structure 6012-1. In other embodiments, an upper portion of the first channel structure 6012-1 is partially removed by the etching operation that removes the dummy layer 6042.

In stage 600C in FIG. 6A, undercut regions 6048AU are formed at the first dummy gate structure 6046A. The undercut regions 6048AU form a space below the spacers 6036 such that a first virtual vertical reference line REF1 extending parallel to the Z-axis passes through a spacer 6036 and passes through the space of the open undercut region 6048AU. In some embodiments, a lower region of the spacers 6036 and/or an upper portion of the first channel structure 6012-1 is partially removed by the etching operation for etching the dummy layer 6042, forming the undercut regions 6048AU. In other embodiments, undercut regions are not formed.

In stage 600D, at least a portion of the first channel structure 6012-1 of the first dummy gate structure 6046A is removed through the opening 6048A. In the embodiment shown in FIG. 6B, a central portion of the first channel structure 6012-1 is removed while a first portion 6012-1-1 and a second portion 6012-1-2 of the first channel structure 6012-1 of the first dummy gate structure 6046A are allowed to remain at sides of the removed central portion, adjacent to the corresponding source/drain structures 6022A and 6022B. In some embodiments, portions 6012-1-1 and 6012-1-2 of the first channel structure 6012-1 include lightly-doped regions (e.g., LDD regions) of the first channel structure 6012-1. In other embodiments (not shown in FIG. 6B), the first channel structure 6012-1 of the first dummy gate structure 6046A is completely removed.

In the example stage 600D in FIG. 6B, the open region formed by removing a portion of the first channel structure 6012-1 of the first dummy gate structure 6046A expands the undercut regions 6048AU (see stage 600C). A second virtual vertical reference line REF2 extending parallel to the Z-axis at a lateral extent of the etched first channel structure 6012-1 (i.e., at an exposed face of the first portion 6012-1-1) is thus closer to a sidewall of the source/drain structure 6022A than the first virtual vertical reference line REF1. In some embodiments, the open region formed by removing a portion of the first channel structure 6012-1 of the first dummy gate structure 6046A has a shape similar to that of an inverted mushroom or dumbbell.

In other embodiments (not shown in FIG. 6B), substantially the entire first channel structure 6012-1 is removed from the first dummy gate structure 6046A, e.g., to expose sidewalls of the source/drain structures 6022A and 6022B. That is, the first portion 6012-1-1 and the second portion 6012-1-2 are removed from the first channel structure 6012-1 of the first dummy gate structure 6046A.

The partial or complete removal of the first channel structure 6012-1 from the first dummy gate structure 6046A results in the uppermost channel structure of the first dummy gate structure 6046A being deactivated, i.e., made non-functional, such that the first dummy gate structure 6046A has two functional channel structures (the second channel structure 6012-2 and the third channel structure 6012-3).

In stage 600E, an insulating structure 6014 is formed in the opening formed by removal of the upper portion of the first dummy gate structure 6046A and the at least partial removal of the first channel structure 6012-1 from the first dummy gate structure 6046A.

In FIG. 6B, the insulating structure 6014 contacts the first portion 6012-1-1 and the second portion 6012-1-2 of the first channel structure 6012-1. In some embodiments, the first portion 6012-1-1 and the second portion 6012-1-2 are lightly-doped regions, and the insulating structure 6014 is in contact with the lightly-doped regions.

In other embodiments, the first channel structure 6012-1 is completely removed from the first dummy gate structure 6046A, e.g., to expose sidewalls of the source/drain structures 6022A and 6022B, and the insulating structure 6014 is in contact with the sidewalls of the source/drain structures 6022A and 6022B (not shown in FIG. 6B).

Examples of insulating materials used for the insulating structure 6014 include one or more of Al₂O₃, a nitride such as silicon nitride (Si₃N₄), SiO₂, TiO₂, AlN, BN, SiOC, SiCN, SiOCN, SiO₂:F, a hydrogen silsesquioxane, or the like. In some embodiments, the material of the insulating structure 6014 is porous or includes voids. In some embodiments, the insulating structure 6014 is a dielectric structure. In some embodiments, the insulating structure 6014 includes a dielectric material having a dielectric constant κ greater than 3, e.g., greater than 3.9, e.g., 6, 7, 10, or more than 10. In some embodiments, forming the insulating structure 6014 of higher-κ materials helps to improve electrical properties of the device and/or improve fabrication processes.

In some embodiments, forming the insulating structure 6014 includes depositing an insulating material in the opening formed by removal of the upper portion of the first dummy gate structure 6046A and the at least partial removal of the first channel structure 6012-1 from the first dummy gate structure 6046A, and across a surface of the device, and then planarizing the insulating material, e.g., to expose contact etch stop layers (CESL) 6034.

In some embodiments, the insulating structure 6014 has a shape similar to that of an inverted mushroom or dumbbell.

In stage 600F, the insulating structure 6014 is partially removed or pulled back to reopen a portion of the opening 6048A. In some embodiments, the pull-back of the insulating structure 6014 helps increase a landing area for a later-formed contact, e.g., a gate contact for a gate formed in place of the first dummy gate structure 6046A, a contact for either of the source/drain structures 6022A and 6022B, or the like. In other embodiments (not shown in FIG. 6B), the pull-back is not performed or performed to a lesser degree such that an upper extent of the insulating structure 6014 is higher than shown in FIG. 6B.

In FIG. 6B, a third virtual horizontal reference line REF3 extends parallel to the X-axis and is located at an uppermost extent of the first channel structure 6012-1. In stage 600F, the partial removal or pull-back of the insulating structure 6014 results in portions 6014P or tips of the insulating structure 6014 extending above the third virtual horizontal reference line REF3. That is, uppermost extents (6014P) of the insulating structure 6014 are higher than (i.e., farther away from the substrate than) the uppermost extent of the first channel structure 6012-1. The portions 6014P or tips of the insulating structure 6014 of the insulating structure 6014 that extend above the third virtual horizontal reference line REF3 in stage 600F therefore distinguish the insulating structure 6014 from, e.g., an oxide of the first channel structure 6012-1 in the first dummy gate structure 6046A.

In other embodiments, the insulating structure 6014 is thicker, e.g., the pull-back of the insulating structure 6014 is less, such that the uppermost extent of the insulating structure 6014 (e.g., uppermost extents of the portions 6014P) is higher than the third virtual horizontal reference line REF3.

In other embodiments, the insulating structure 6014 is thinner, e.g., the insulating structure 6014 is pulled back to be entirely below the third virtual horizontal reference line REF3, i.e., below an uppermost extent of the first channel structure 6012-1, such that portions 6014P or tips of the insulating structure 6014 are not present above the third virtual horizontal reference line REF3.

In other embodiments, no pull-back is performed, and the insulating structure 6014 has an upper extent that corresponds to that of, e.g., the upper extent of the contact etch stop layers (CESL) 6034.

In FIG. 6B, a fourth virtual horizontal reference line REF4 extends parallel to the Y-axis and is located at an uppermost extent of the dummy layer 6042, and an uppermost extent of the insulating structure 6014 is even with the fourth virtual horizontal reference line REF4. In some embodiments, the uppermost extent of insulating structure 6014 that is even with the uppermost extent of the dummy layer 6042 of the first dummy gate structure 6046A distinguishes the insulating structure 6014 from, e.g., an oxide of the first channel structure 6012-1 in the first dummy gate structure 6046A.

In other embodiments, the uppermost extent of insulating structure 6014 is above the fourth virtual horizontal reference line REF4, i.e., above the uppermost extent of the dummy layer 6042 of the first dummy gate structure 6046A. In some embodiments, the uppermost extent of insulating structure 6014 that is above the uppermost extent of the dummy layer 6042 of the first dummy gate structure 6046A distinguishes the insulating structure 6014 from, e.g., an oxide of the first channel structure 6012-1 in the first dummy gate structure 6046A.

In still other embodiments, the uppermost extent of insulating structure 6014 is below the fourth virtual horizontal reference line REF4, i.e., below the uppermost extent of the dummy layer 6042 of the first dummy gate structure 6046A.

In FIG. 6B, a fifth virtual vertical reference line REF5 extends parallel to the Z-axis and is located at a lateral extent of a lower portion of the insulating structure 6014, and a sixth virtual vertical reference line REF6 extends parallel to the Z-axis and is located at a lateral extent of an upper portion of the insulating structure 6014. The sixth virtual vertical reference line REF6 corresponding to the lateral extent of the upper portion of the insulating structure 6014 is offset in the Y-axis direction toward the center of the first dummy gate structure 6046A relative to the fifth virtual vertical reference line REF5 corresponding to the lateral extent of the lower portion of the insulating structure 6014. The upper portion of the insulating structure 6014 is thus narrower in the Y-axis direction (or Y-Z plane) than the lower portion of the insulating structure 6014, i.e., a first width W01 of the upper portion of the insulating structure 6014 in the Y-axis direction is less than a second width W02 of the lower portion of the insulating structure 6014 in the Y-axis direction (W01<W02 in the Y-Z plane). Thus, it can be viewed as the upper portion of the insulating structure 6014 corresponding to a vestigial portion of a stem of a mushroom-shaped structure or a vestigial portion of a waist of a dumbbell-shaped structure.

In other embodiments (not shown in FIG. 6B), the opening 6048A is made greater in the Y-axis direction such that the W01 is approximately the same as W02 in the Y-Z plane. In still other embodiments (not shown in FIG. 6B), the opening 6048A is made greater in the Y-axis direction such that the W01>W02 in the Y-Z plane.

In stage 600G, the first and second dummy gate structures 6046A and 6046B are removed from over the dummy layer 6042. In some embodiments, the first and second dummy gate structures 6046A and 6046B include polysilicon and a selective etch operation is performed to remove the polysilicon so as to expose the dummy layer 6042, and to expose at least part of the sidewalls of the insulating structure 6014. In some embodiments, the etch operation is a dry etching operation. In some embodiments, removing the first and second dummy gate structures 6046A and 6046B includes partially removing the dummy layer 6042.

In stage 600H, the dummy layer 6042 and the sacrificial layers 6040 are removed in preparation for forming a first gate structure having two functional channels (the second channel structure 6012-2 and the third channel structure 6012-3 at first cross-section ‘A’) and forming a second gate structure having three functional channels (the first, second, and third channel structures 6012-1, 6012-2, and 6012-3 at second cross-section ‘B’). In some embodiments, the channel structures 6012 are nanosheets of a semiconductor material, e.g., epitaxial silicon or the like, and the removal of the sacrificial layers 6040 is referred to as a nanosheet release operation. In some embodiments, after the dummy layer 6042 and the sacrificial layers 6040 are removed, a doping operation is performed to dope the channel structures 6012-1, 6012-2, and 6012-3 to form lightly-doped regions, e.g., LDD regions, adjacent to sidewalls of the source/drain structures 6022A and 6022B. In other embodiments, forming LDD regions is done in connection with an earlier processing stage or a later processing stage.

A height H01 in FIG. 6C represents a height in the Z-axis direction (Y-Z plane) of the insulating structure 6014. A height H02 in FIG. 6C represents a height in the Z-axis direction (Y-Z plane) of the first channel structure 6012-1. In stage 600H, the height H01 of the insulating structure 6014 is greater than the height H02 of the first channel structure 6012-1 (H01>H02).

In other embodiments, the uppermost extent of insulating structure 6014 is lower such that H01 is approximately the same as H02, or still lower such that H01<H02, e.g., by continuing the pull-back of the insulating structure 6014 (see stage 600F) such that the insulating structure 6014 is further removed by the pull-back operation.

In stage 600H, the insulating structure 6014 has the first width W01 in the Y-axis direction at the upper portion of the insulating structure 6014 and has the second width W02 in the Y-axis direction at the lower portion of the insulating structure 6014. The first width W01 is less than the second width W02 (W01<W02 in the Y-Z plane). Also, the insulating structure 6014 has a third width W03 in the X-axis direction (X-Z plane).

The removal of the sacrificial layers 6040 creates openings 6050 where the sacrificial layers 6040 used to be. The openings 6050 have a width W04 in the X-axis direction (X-Z plane). In some embodiments, the operation (e.g., an etch operation) that removes the sacrificial layers 6040 is selective for the material of the sacrificial layers 6040 (e.g., SiGe, an oxide of SiGe, an oxide of silicon, or the like) relative to a material of the inner spacers 6028 (e.g., amorphous silicon, or a dielectric material such as silicon oxide, silicon nitride, silicon carbide, silicon oxynitride, SiCN, silicon oxycarbide, SiOCN, a material with a dielectric constant κ<7, or the like) such that the inner spacers 6028 remain to define lateral extents of the openings 6050 in the X-Z plane. In this case, the width W04 corresponds to a distance between facing ones of the inner spacers 6028.

In the embodiment of stage 600H, the width W03 of the insulating structure 6014 is greater than the width W04 of the opening 6050 between facing ones of the inner spacers 6028 (W03<W04 in the X-Z plane). The insulating structure 6014 extends laterally in the X-axis direction beyond lateral extents in the X-axis of the underlying opening 6050.

Stage 600I is illustrated in brief in FIG. 6C and is illustrated in further detail in FIGS. 6D-1 and 6D-2.

In stage 600I, a gate dielectric layer 6018 is formed over the channel structures 6012 and a gate electrode layer 6020 is formed over the gate dielectric layer 6018 to form a first gate structure 6016A surrounding two channel structures (corresponding to cross-section ‘A’) and a second gate structure 6016B surrounding three channel structures (corresponding to cross-section ‘B’). The gate dielectric layer 6018 and the gate electrode layer 6020 also surround the insulating structure 6014. The gate dielectric layer 6018 isolates the gate electrode layer 6020 from the channel structures 6012-1, 6012-2, and 6012-3, and isolates the gate electrode layer 6020 from the insulating structure 6014.

The first and second gate structures 6016A and 6016B may be referred to individually or collectively as gate structures 6016. In some embodiments, the gate structures 6016 are gate all-around (GAA) structures.

In some embodiments, the gate dielectric layer 6018 is or includes a high-κ dielectric material. In some embodiments, the gate dielectric layer 6018 includes one or more of Gd₂O₅, HfAlO, HfErO, HfGdO, HfLaO, HfO₂, HfTaO, HfTiO, HfYO, HfZrO, La₂O₅, SrTiO, Ta₂O₅, TiO₂, Y₂O₃, ZrO₂, or the like. In some embodiments, the gate dielectric layer 6018 is formed of a different insulating material than an insulating material forming the insulating structure 6014.

In some embodiments, the gate electrode layer 6020 is or includes a conductive material such as polysilicon or a metal. In some embodiments, the gate electrode layer 6020 includes aluminum (Al), tungsten (W), copper (Cu), a combination of two or more thereof, or the like.

Referring to FIG. 6D-1, the insulating structure 6014 has the width W03 in the X-axis direction (X-Z plane). The first gate structure 6016A occupies, among other things, the opening 6050 immediately below the insulating structure 6014. The opening 6050 immediately below the insulating structure 6014 had the width W04 in the X-axis direction. Thus, the portion of the first gate structure 6016A that is immediately below the insulating structure 6014 also has the width W04 in the X-axis direction. The width W03 of the insulating structure 6014 is greater than the width W04 of the portion of the first gate structure 6016A that is immediately below the insulating structure 6014 (W03>W04).

Referring to FIG. 6D-2, the insulating structure 6014 has the height W01 in the Z-axis direction (Y-Z plane). Thus, at the level of the first channel structure 6012-1, the portion of the first gate structure 6016A that surrounds the insulating structure 6014 has inner surfaces that are spaced apart in the Z-axis direction by the height W01. On the other hand, at the level of the first channel structure 6012-1, the portion of the second gate structure 6016B that surrounds the first channel structure 6012-1 has inner surfaces that are spaced apart in the Z-axis direction by a height W02 that is less than the height W01 (H02<H01).

In another approach, a channel structure can be deactivated or inactivated by, e.g., oxidizing a portion of the channel structure. In the other approach, the deactivated portion of the channel structure is thus an oxide of the material forming the channel structure. According to some embodiments, a dielectric material of the insulating structure 6014 has a dielectric constant that is greater than a dielectric constant of an oxide of the first channel structure 6012-1. Also, in the other approach, oxidizing the channel structure produces a structure having dimensions that generally correspond to the unoxidized channel structure. On the other hand, according to some embodiments, the insulating structure 6014 has a thickness in the Z-axis direction that is greater than that of the (removed) first channel structure 6012-1 and greater than that of an oxidized first channel structure 6012-1. Even in the case that an oxide of the first channel structure 6012-1 increases in thickness relative to the unoxidized channel structure, in some embodiments the insulating structure 6014 nevertheless is formed to have a greater thickness than the oxide of the first channel structure 6012-1. In some embodiments the insulating structure 6014 extends higher (i.e., relative to the substrate) than the previously-present first channel structure 6012-1 did at the cross-section ‘A’and extends higher than would an oxide of the first channel structure 6012-1.

The first gate structure 6016A occupies, among other things, the opening 6050 immediately below the insulating structure 6014. The opening 6050 immediately below the insulating structure 6014 had the width W04 in the X-axis direction. Thus, the portion of the first gate structure 6016A that is immediately below the insulating structure 6014 also has the width W04 in the X-axis direction. The width W03 of the insulating structure 6014 is greater than the width W04 of the portion of the first gate structure 6016A that is immediately below the insulating structure 6014 (W03>W04).

Due to the shape of the insulating structure 6014, an interface of the gate dielectric layer 6018 with the gate electrode layer 6020 directly above the insulating structure 6014 in the first gate structure 6016A is higher (i.e., in the Z-direction or relative to the substrate 6010) than the interface of the gate dielectric layer 6018 with the gate electrode layer 6020 directly above the first channel structure 6012-1 in the second gate structure 6016B. This difference in height is indicated by a height difference D01 in FIG. 6D-2.

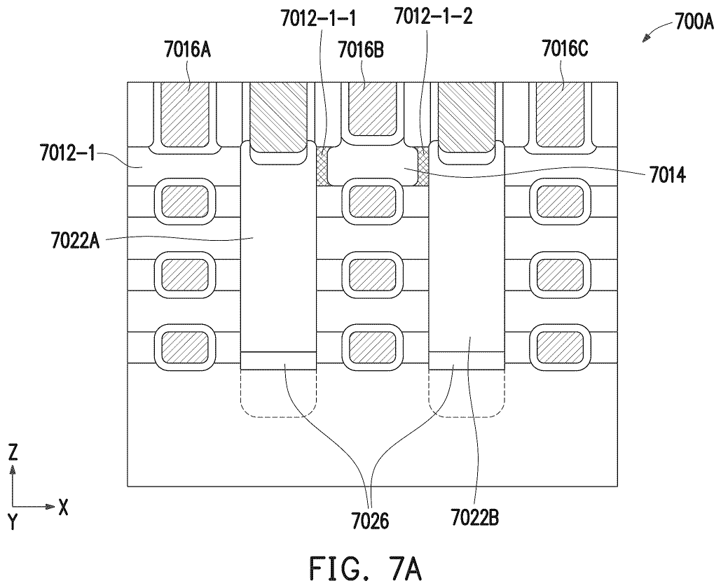

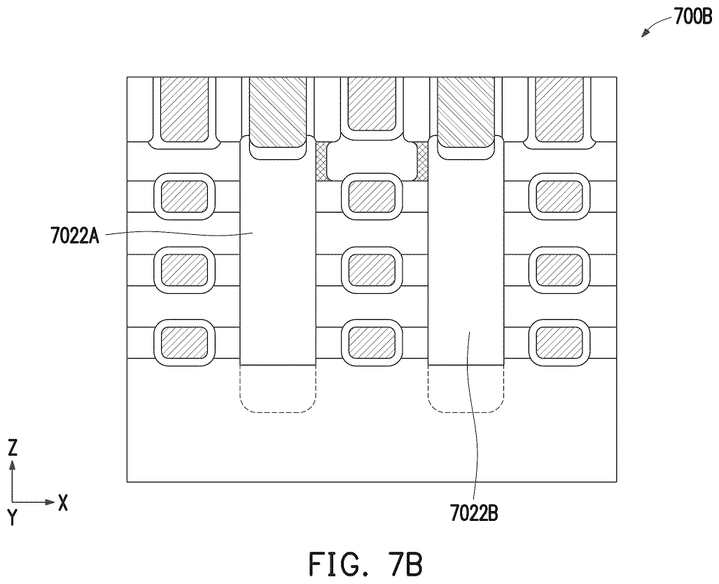

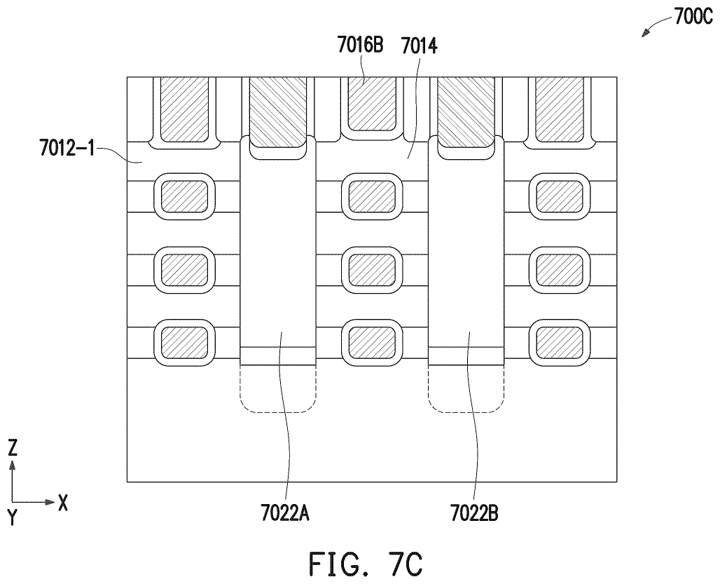

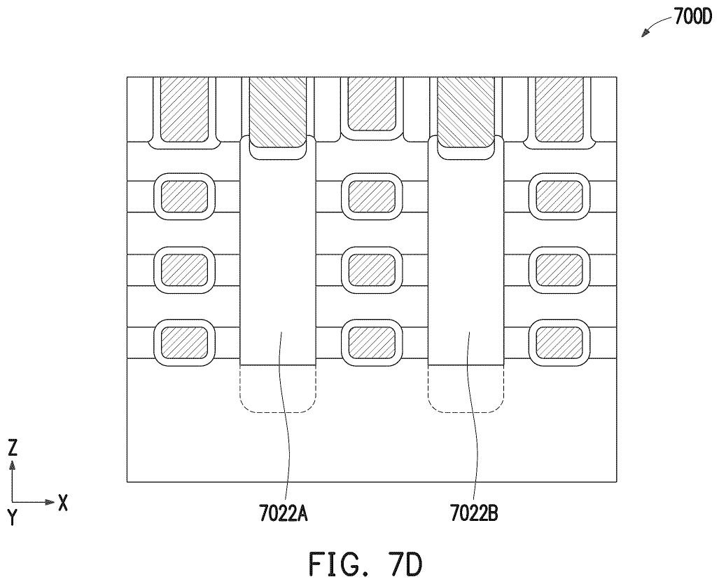

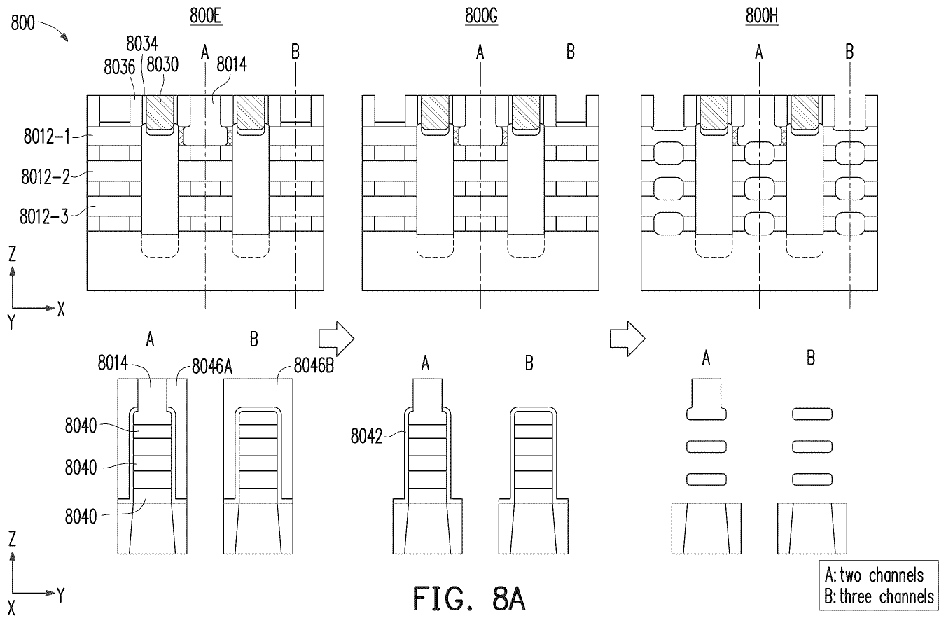

FIGS. 7A, 7B, 7C, and 7D are cross-sections of respective semiconductor devices 700A, 700B, 700C, and 700D according to some embodiments.

The semiconductor devices 700A, 700B, 700C, and 700D are examples in which a bottom isolation layer (flexible bottom insulator or flexible bottom isolation (FBI)) is variously include or not included, and in which an uppermost channel structure is variously removed in part or removed completely from a given gate structure.

In detail, the semiconductor device 700A includes a bottom isolation layer 7026 at a lower region of a source/drain structure 7022A and a lower region of a source/drain structure 7022B. Further, in deactivating the uppermost channel structure, i.e., a first channel structure 7012-1 of a second gate structure 6016B in the semiconductor device 700A, the first channel structure 7012-1 is partially removed. As such, in a gate structure 7016B, portions 7012-1-1 and 7012-1-2 of the first channel structure 7012-1 remain on lateral sides of an insulating structure 7014. In some embodiments, the portions 7012-1-1 and 7012-1-2 are lightly-doped regions (e.g., LDD regions). Partially removing the first channel structure 7012-1 can help to avoid etching sidewalls of the source/drain structures 7022A and 7022B when using an etching operation to remove the first channel structure 7012-1. In some embodiments, an etching operation that is used to remove the first channel structure 7012-1 (in connection with forming the insulating structure 7014 and deactivating the uppermost channel structure) is performed to allow portions 7012-1-1 and 7012-1-2 to remain covering the sidewalls of the source/drain structures 7022A and 7022B to protect the sidewalls of the source/drain structures 7022A and 7022B against etching.

In some embodiments, the semiconductor device 700B is the same as the semiconductor device 700A except that the semiconductor device 700B does not include a bottom isolation layer (see 7026 in semiconductor device 700A) at a lower region of the source/drain structures 7022A and 7022B.

In some embodiments, the semiconductor device 700C is the same as the semiconductor device 700A except that, in deactivating the uppermost channel structure, i.e., the first channel structure 7012-1 of the second gate structure 6016B in the semiconductor device 700C, the first channel structure 7012-1 is completely removed. In some embodiments, in the semiconductor device 700C, the insulating structure 7014 directly contacts sidewalls of the source/drain structures 7022A and 7022B, and no LDD regions remain in the first channel structure 7012-1 in the gate structure 7016B, which can beneficially reduce LDD capacitance.

In some embodiments, the semiconductor device 700D is the same as the semiconductor device 700C except that the semiconductor device 700D does not includes a bottom isolation layer at a lower region of the source/drain structures 7022A and 7022B.

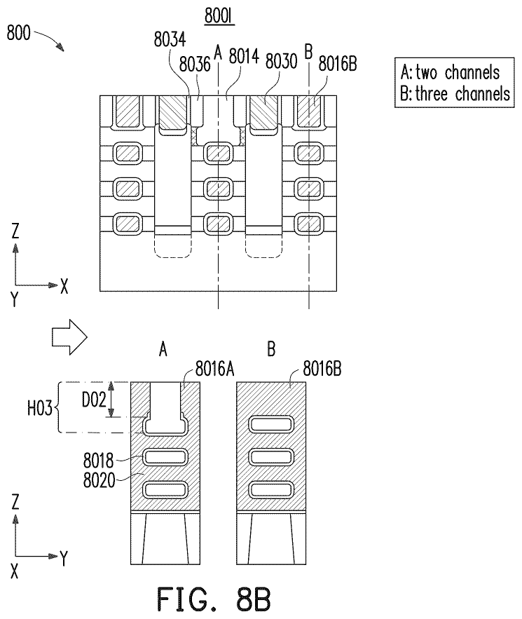

FIGS. 8A and 8B are cross-sectional views of stages in a method 800 of fabricating a semiconductor device according to some embodiments.

FIGS. 8A and 8B show sequential stages 800E, 800G, 800H, and 800I of the method 800. Additional fabrication operations before stage 800A and/or after stage 800I can also be performed. Additional fabrication operations between any of stages 800E, 800G, 800H, and 800I can also be performed. Further, one or more of stages 800E, 800G, 800H, or 800I are omitted or replaced in some embodiments.

The method 600 described above includes stage 600F in which the insulating structure 6014 that at least partially replaces the uppermost channel structure 6012-1 is partially removed or pulled back. The method 800 omits pull-back of insulating structure 8014. FIGS. 8A and 8B illustrate stages 800E, 800G, 800H, and 800I of the method 800. In some embodiments, the method 800 includes operations prior to stage 800E, e.g., operations corresponding to operations 600A ~600E of the method 600. In the following, some details may be described briefly or omitted in connection with the method 800 but in such cases reference should be made to the details of the method 600 described above. The following description will focus on aspects of the method 800 that are different from the method 600 due to omitting the pull-back of the insulating structure 8014 in the method 800.

Also, the semiconductor device formed in the method 800 does not include a bottom isolation layer (flexible bottom insulator or flexible bottom isolation (FBI)). In other embodiments, the semiconductor device formed in the method 800 does include a bottom isolation layer corresponding to the bottom isolation layer 6026 of the method 600. It will be understood that inclusion or omission of the pull-back of the insulating structure is independent of the inclusion or omission of the bottom isolation layer.

In the method 800, the stage 800E in FIG. 8A is substantially the same as the stage 600E of the method 600, except that the bottom isolation structure is omitted in the stage 800E of FIG. 8A. Briefly, in stage 800E a cross-section ‘A’ corresponds to a transistor having two channel structures and the insulating structure 8014 occupying at least a portion of a disabled first channel structure 8012-1 (uppermost channel structure), and a cross-section ‘B’ corresponds to a transistor having three channel structures.

In some embodiments, in the stage 800E, forming the insulating structure 8014 includes depositing an insulating material in an opening formed by removal of the upper portion of a first dummy gate structure 8046A and the at least partial removal of the first channel structure 8012-1 from the first dummy gate structure 8046A, and across a surface of the device, and then planarizing the insulating material, e.g., to expose contact etch stop layers (CESL) 8034.

In some embodiments, the insulating structure 8014 has a shape similar to that of an inverted mushroom or dumbbell.

In stage 800G, first and second dummy gate structures 8046A and 8046B are removed.

In stage 800H, dummy layer 8042 and the sacrificial layers 8040 are removed in preparation for forming a first gate structure having two functional channels (at cross-section ‘A’) and forming a second gate structure having three functional channels (at cross-section ‘B’). In some embodiments, channel structures 8012-1, 8012-2, and 8012-3 are nanosheets of a semiconductor material, e.g., epitaxial silicon or the like, and the removal of the sacrificial layers 8040 is referred to as a nanosheet release operation.

In stage 800I, a gate dielectric layer 8018 is formed over the channel structures 8012-1, 8012-2, and 8012-3 and a gate electrode layer 8020 is formed over the gate dielectric layer 8018 to form a first gate structure 8016A surrounding two channel structures (corresponding to cross-section ‘A’) and a second gate structure 8016B surrounding three channel structures (corresponding to cross-section ‘B’). The gate dielectric layer 8018 and the gate electrode layer 8020 also at least partially surround the insulating structure 8014. The gate dielectric layer 8018 isolates the gate electrode layer 8020 from the channel structures 8012-1, 8012-2, and 8012-3, and at least partially isolates the gate electrode layer 8020 from the insulating structure 8014.

In FIG. 8B, an upper surface of the insulating structure 8014 is exposed by, i.e., is not entirely covered by, the gate dielectric layer 8018 and the gate electrode layer 8020. In some embodiments, a gate via (VG) for the first gate structure 8016A is laterally offset from the insulating structure 8014. In some embodiments, a gate via (VG) for the first gate structure 8016A does not vertically overlap the insulating structure 8014 such that a virtual vertical line passing through the gate via for the first gate structure 8016A does not pass through the insulating structure 8014.

A height H03 in FIG. 8B represents a height in the Z-axis direction (Y-Z plane) of the insulating structure 8014. The height H03 is greater than the height H01 of the insulating structure 6014 in FIG. 6D-2 due to the omission of the pull-back of the insulating structure 8014. In some embodiments, the height H03 corresponds to a distance in the Z-axis direction between a lower extent of the insulating structure 8014 and an upper extent of the gate electrode layer 8020. In some embodiments, the height H03 corresponds to a distance in the Z-axis direction between a lower extent of the insulating structure 8014 and the upper extent of another feature, e.g., an upper extent of the adjacent contact etch stop layer (CESL) 8034, an upper extent of spacer 8036, and upper extent of adjacent second gate structure 8016B, an upper extent of an adjacent contact structure 8030, or the like.

In FIG. 8B, a distance D02 represents a difference in heights between the insulating structure 6014 and the insulating structure 8014. The additional height of the insulating structure 8014 represented by the distance D02 results in a reduction on the amount of gate electrode layer material over the insulating structure 8014 relative to the structure in FIGS. 6D-1 and 6D-2. In some embodiments, the gate electrode layer material is a metal and reducing the amount of the gate metal yields a beneficial reduction in capacitance for the first gate structure 8016A.

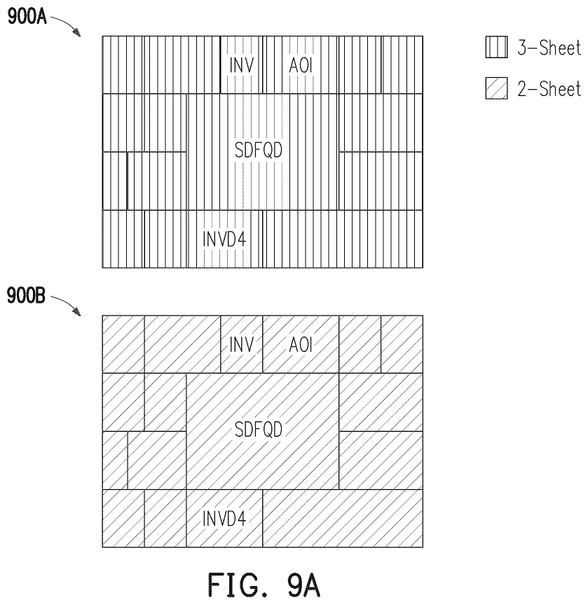

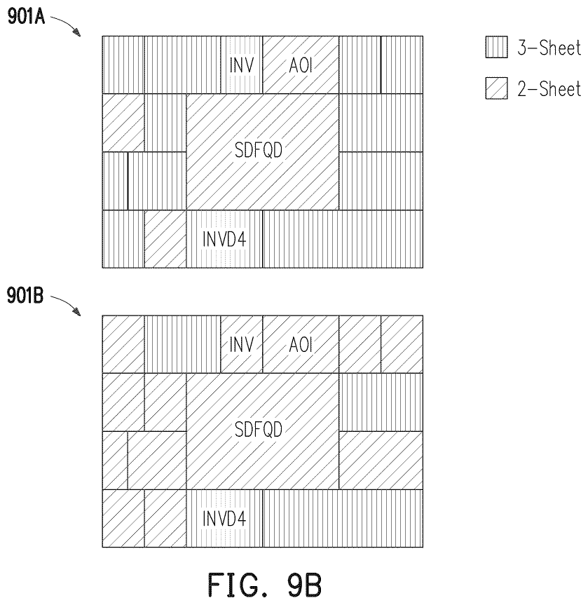

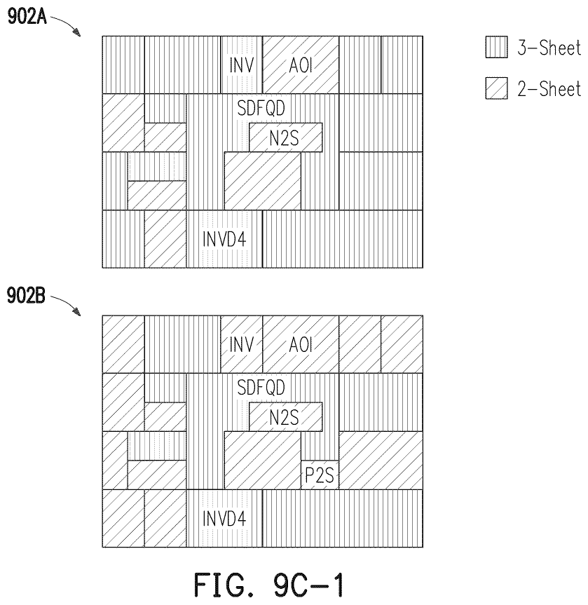

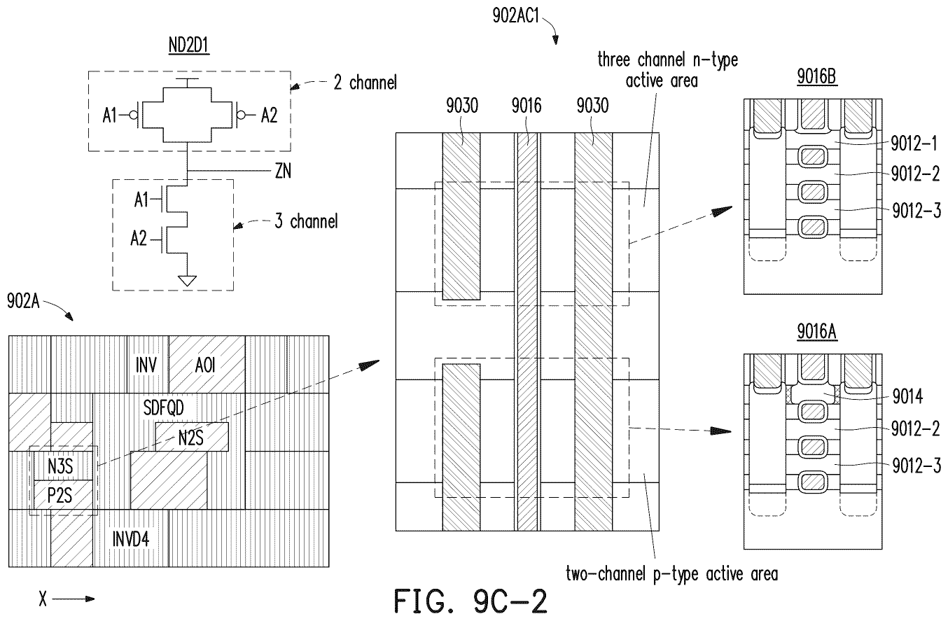

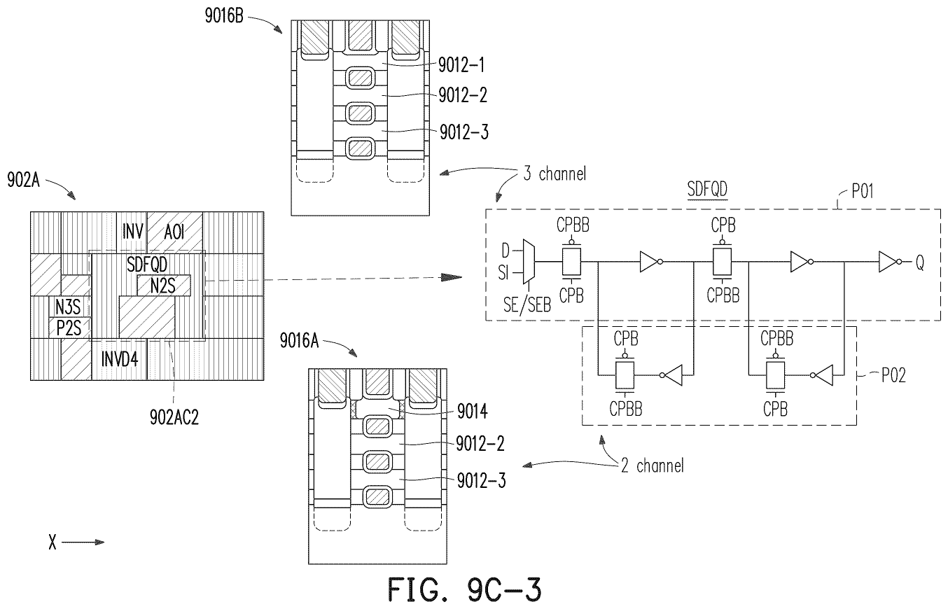

FIG. 9A is a layout diagram of a processor 900A and a system-on-chip (SoC) 900B according to some embodiments.

An example of the processor 900A is a central processing unit (CPU). By way of example, each of the processor 900A and the SoC 900B includes circuits INV (inverter), AOI (AND-OR-invert), SDFQD (scan D-flip-flop), and INVD4 (inverter with a relative driving strength of 4). However, embodiments are not limited to the particular type or arrangement of the circuits. One or more of the circuits can be omitted or replaced with other circuits and the circuits can span one row, a portion of a row, or more than one row.

In the example in FIG. 9A, the processor 900A is implemented with transistors, e.g., gate all-around (GAA) transistors, each of which has two channels, e.g., two nanosheets where an uppermost nanosheet (third nanosheet) is disabled. Examples of such two-channel transistors are the transistors in regions RB of FIGS. 1 and 3, in which an uppermost nanosheet is partially replaced (FIG. 1) or completely replaced (FIG. 3) by the insulating structure 1014.

In the example in FIG. 9A, the SoC 900B is implemented with transistors, e.g., gate all-around (GAA) transistors, each of which has three channels, e.g., three nanosheets where all three nanosheets are functional (i.e., an uppermost nanosheet is not disabled). An example of such three-channel transistors is the transistor in region RC of FIG. 4.

FIG. 9A is an example of layouts that select among the two-channel or three-channel transistors on a block level within chips. Thus, for example, in FIG. 9A, all of the transistors in the processor 900A have three nanosheets and all of the transistors in the SoC 900B have two nanosheets.

FIG. 9B is a layout diagram of a processor 901A and a system-on-chip (SoC) 901B according to some embodiments.

For ease of comparison with FIG. 9A, each of the processor 901A and the SoC 901B includes the same circuits INV, AOI, SDFQD, and INVD4 as in FIG. 9B. However, embodiments are not limited to the particular type or arrangement of the circuits. One or more of the circuits can be omitted or replaced with other circuits, and the circuits can span one row height, a portion of a row height, or more than one row height.

In the example in FIG. 9B, the processor 901A is implemented with a mix of standard cells using transistors, e.g., gate all-around (GAA) transistors, in which some standard cells are formed of transistors that have two channels (e.g., the transistors in regions RB of FIGS. 1 and 3) and other standard cells are formed of transistors that have three channels (e.g., the transistor in region RC of FIG. 4).

In the example in FIG. 9B, the SoC 901B is also implemented with a mix of standard cells using transistors, e.g., gate all-around (GAA) transistors, in which some standard cells are formed of transistors that have two channels (e.g., the transistors in regions RB of FIGS. 1 and 3) and other standard cells are formed of transistors that have three channels (e.g., the transistor in region RC of FIG. 4).

FIG. 9B is an example of layouts that select among the two-channel or three-channel transistors on a standard cell level within blocks. Thus, for example, in FIG. 9B, all of the transistors in the INV and INVD4 circuit cells of processor 900A have three nanosheets, all of the transistors in the AOI and SDFQD circuit cells of processor 900A have two nanosheets (with a third, uppermost nanosheet disabled), all of the transistors in the INVD4 circuit cell in the SoC 900B have three nanosheets, and all of the transistors in the INV, AOI, and SDFQD circuit cells in the SoC 900B have two nanosheets (with a third, uppermost nanosheet disabled).

In some embodiments, a standard cell in the processor 901A that is implemented using more three-channel transistors is faster than the same standard cell implemented using more two-channel transistors. In some embodiments, the percentage of three-channel transistors from among at total number of two-channel and three-channel transistors in the processor 901A is, e.g., about 50% or more, e.g., 50% to 80% or 50% to 90%. In some embodiments, a standard cell in the SoC 901B that is implemented using more two-channel transistors exhibits lower power consumption (i.e., better Peff) than the same standard cell implemented using more three-channel transistors. In some embodiments, the percentage of two-channel transistors from among at total number of two-channel and three-channel transistors in the SoC 901B is, e.g., 50% to 70%. In some embodiments, for ease of manufacturing, a same number n of sheets is initially formed within each row, and an upper nanosheet is selectively disabled for cells having (n-1) nanosheet transistors.

FIG. 9C-1 is a layout diagram of a processor 902A and a system-on-chip (SoC) 902B according to some embodiments.

For ease of comparison with FIGS. 9A and 9B, each of the processor 902A and the SoC 902B includes the same circuits INV, AOI, SDFQD, and INVD4 as in FIGS. 9A and 9B. However, embodiments are not limited to the particular type or arrangement of the circuits. One or more of the circuits can be omitted or replaced with other circuits and the circuits can span one row, a portion of a row, or more than one row.

In the example in FIG. 9C-1, the processor 902A is implemented with a mix of transistors, e.g., gate all-around (GAA) transistors, in at least some of the standard cells, such that some standard cells have first transistors having two channels (e.g., the transistors in regions RB of FIGS. 1 and 3) and have second transistors having three channels (e.g., the transistor in region RC of FIG. 4).

In the example in FIG. 9C-1, the SoC 901B is also implemented with a mix of transistors, e.g., gate all-around (GAA) transistors, in at least some of the standard cells, such that some standard cells have first transistors having two channels (e.g., the transistors in regions RB of FIGS. 1 and 3) and have second transistors having three channels (e.g., the transistor in region RC of FIG. 4).

FIG. 9C-1 is an example of layouts that select among the two-channel or three-channel transistors on a transistor level within cells. Thus, for example, the SDFQD circuit cells in the processor 902A and the SoC 902B include both two-channel and three-channel transistors. Additional examples will now be described in connection with FIGS. 9C-2 and 9C-3.

FIG. 9C-2 is an example of the processor 902A implemented to include a first cell 902AC1 that is an ND2D1-type (two input, 1*D current-driving strength) NAND gate implemented using both two and three-channel transistors, e.g., two-and three-nanosheet GAA transistors.

In FIG. 9C-2, channel structures 9012, e.g., nanosheet structures, extend in the X-axis direction. A gate electrode 9016 and contact structures 9030 cross the channel structures 9102. A first transistor 9016A of the first cell 902AC1 includes second and third channel structures 9012-2 and 9012-3, and an uppermost channel structure 9012-1 is disabled by an insulating structure 9014. The first transistor 9016A is a p-type transistor. A second transistor 9016B of the first cell 902AC1 includes first, second, and third channel structures 9012-1, 9012-2, and 9012-3. The second transistor 9016B is an n-type transistor. In some embodiments, implementing the second transistor 9016B with two p-type channel structures, e.g., p-doped nanosheets, reduces the power consumption of the NAND gate.

In some embodiments, a method of operating a circuit includes applying a gate signal to a gate that is common to first and second transistors such that the gate signal controls current-conducting states, e.g., on/off states, of both of the first and second transistors, where the first transistor has two functional channel structures and a third, disabled channel structure above an uppermost one of the two functional channel structures, and where the second transistor has three functional channel structures of which an uppermost functional channel structure is at a same level or height from a substrate as the disabled channel structure of the first transistor. An example of the first transistor is the first transistor 9016A in the first cell 902AC1. An example of the second transistor is the second transistor 9016B in the first cell 902AC1.

FIG. 9C-3 is an example of the processor 902A implemented to include a second cell 902AC2 that is an SDFQD circuit implemented using both two and three-channel transistors, e.g., two-and three-nanosheet GAA transistors.

In some embodiments, the SDFQD circuit includes a scan D-flip-flop with a data input D, a scan-in input SI, a scan-enable/scan-enable bar input SE/SEB, an inverted clock input CPB, a buffered inverted clock input CPBB, and an output Q.

In FIG. 9C-3, channel structures 9012, e.g., nanosheet structures, extend in the X-axis direction. A first portion P01 of the SDFQD circuit includes transistors in a critical timing path. A second portion P02 of the SDFQD circuit includes transistors that operate to provide latch feedback and are not in the critical timing path. The transistors in the first portion P01 are exemplified by a second transistor 9016B having first, second, and third channel structures 9012-1, 9012-2, and 9012-3. The transistors in the second circuit portion P02 are exemplified by a first transistor 9016A having second and third channel structures 9012-2 and 9012-3, and having an uppermost channel structure 9012-1 disabled by an insulating structure 9014. In some embodiments, implementing second circuit portion P02 with the second transistor 9016B having two channel structures reduces the power consumption of the SDFQD circuit.

In some embodiments, a method of operating a circuit includes applying a gate signal to a first gate of a first transistor in a first portion of the circuit and applying the same gate signal to a second gate of a second transistor in a second portion of the circuit such that the gate signal controls current-conducting states, e.g., on/off states, of both of the first and second transistors, where the first transistor has two functional channel structures and a third, disabled channel structure above an uppermost one of the two functional channel structures, and where the second transistor has three functional channel structures of which an uppermost functional channel structure is at a same level or height from a substrate as the disabled channel structure of the first transistor. An example of the first transistor is the first transistor 9016A in the second portion P02 of the SDFQD circuit of FIG. 9C-3. An example of the second transistor is the second transistor 9016B in the first portion P01 of the SDFQD circuit of FIG. 9C-3.

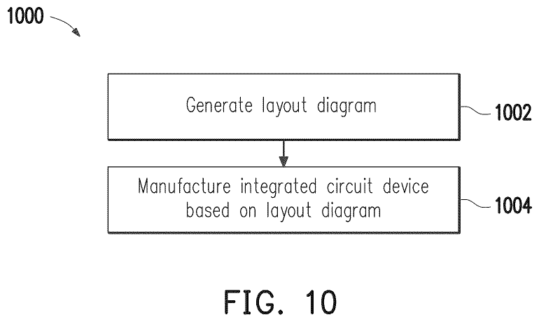

FIG. 10 is a flowchart of a method 1000 of manufacturing a semiconductor device according to some embodiments.

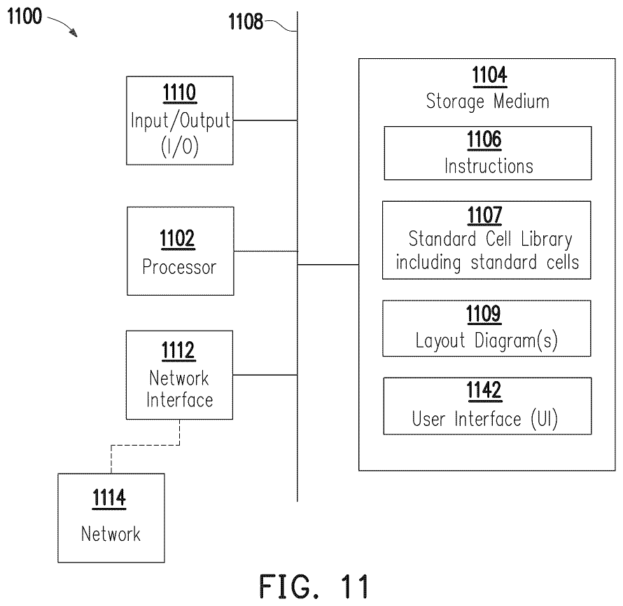

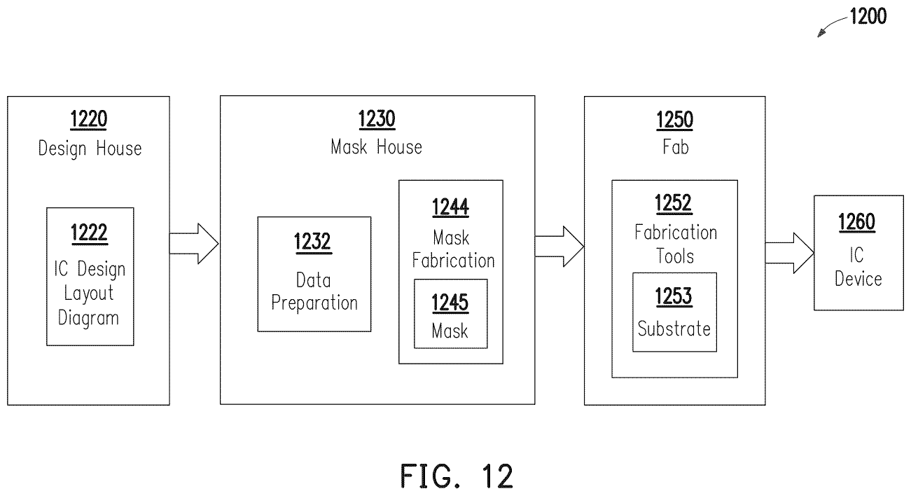

Method 1000 is implementable, for example, using an electronic design automation (EDA) system 1100 (FIG. 11, discussed below) and an integrated circuit (IC) manufacturing system 1200 (FIG. 12, discussed below), according to some embodiments. Examples of a semiconductor device which can be manufactured according to method 900 include one or more of the semiconductor devices 100, 101, 400, 700A, 700B, 700C, and 700D, 900A, 900B, 901A, 901B, 902A, and/or 902B described above.

In FIG. 10, method 1000 includes operations 1002 and 1004. At operation 1002, a layout diagram is generated which, among other things, includes one or more of layout diagrams disclosed herein, or the like.

In some embodiments, the layout diagram generated in operation 1002 includes: in a first conductive layer: a first conductor in a first cell, the first conductor coupled to a gate of a first transistor in the first cell; in a second conductive layer higher than the first conductive layer: a second conductor in a second cell that adjoins the first cell at a cell boundary, and a pin conductor in the first cell and adjoining the cell boundary, the second conductor extending in the second cell and being coupled between a source/drain region of a second transistor in the second cell and the pin conductor; and, in a third conductive layer higher than the second conductive layer: a third conductor in the first cell and forming at least a portion of a conductive path in the first cell between the first conductor and the second conductor, the third conductor being spaced apart from the cell boundary, the third conductive layer being a highest conductive layer among conductive layers forming the conductive path in the first cell.

Operation 1002 is implementable, for example, using the EDA system 1100 (FIG. 11, discussed below), according to some embodiments. In some embodiments, operation 1002 includes generating shapes corresponding to structures in a semiconductor diagram which are to be represented.

At operation 1004, based on the layout diagram, at least one of (A) one or more photolithographic exposures are made or (B) one or more semiconductor masks are fabricated or (C) one or more components in a layer of an integrated circuit (IC) device, e.g., a semiconductor device, are fabricated. In some embodiments, operation 1004 includes one or more operations described above in connection with the methods 600 and/or 800. See also discussion below.

FIG. 11 is a block diagram of the EDA system 1100 according to some embodiments. The EDA system 1100 is usable to design one or more of the semiconductor devices 100, 101, 400, 700A, 700B, 700C, and 700D, 900A, 900B, 901A, 901B, 902A, and/or 902B described above.

In some embodiments, the EDA system 1100 includes an APR system. In some embodiments, the EDA system 1100 is or includes a general purpose computing device including a hardware processor 1102 and a non-transitory, computer-readable storage medium 1104. The storage medium 1104 is encoded with, i.e., stores, computer program code 1106, i.e., a set of executable instructions. Execution of the instructions 1106 by the processor 1102 represents (at least in part) an EDA tool which implements a portion or all of the methods described herein in accordance with one or more embodiments (hereinafter, the noted processes and/or methods).

In some embodiments, methods described herein of designing layout diagrams representing wire routing arrangements are implementable using the EDA system 1100.

In some embodiments, the EDA system 1100 is configured to perform an APR operation to generate a layout of an IC, e.g., based on a schematic of the IC, the APR operation including a cell placement operation that places a first cell and a second cell in the layout diagram such that the first and second cells adjoin one another at a cell boundary, and a routing operation that routes a net interconnecting the first and second cells in the layout diagram, the routing operation including: routing a first conductive layer such that: a first conductor in the first cell is coupled to a gate of a first transistor in the first cell; routing a second conductive layer, which is higher than the first conductive layer, such that: a second conductor is in the second cell and adjoins the cell boundary, a pin conductor is in the first cell and adjoins the cell boundary, and the second conductor extends in the second cell and is coupled between a source/drain region of a second transistor in the second cell and the pin conductor; and routing a third conductive layer, which is higher than the second conductive layer, such that: a third conductor is in the first cell and forms at least a portion of a conductive path in the first cell between the first conductor and the second conductor, the third conductor being spaced apart from the cell boundary, and the third conductive layer is a highest conductive layer among conductive layers forming the conductive path in the first cell.

In some embodiments, execution of the instructions 1106 by the processor 1102 represents (at least in part) an IC device design system which implements a portion or all of one or more of the noted processes and/or methods.

In some embodiments, a computer program product includes the storage medium 1104 storing instructions therein that, when executed by the processor 1102, cause the processor 1102 to perform a cell placement operation that places a first cell and a second cell in the layout diagram such that the first and second cells adjoin one another at a cell boundary, and perform a first routing operation that routes a net interconnecting the first and second cells in the layout diagram, the first routing operation including: routing a first conductive layer such that: a first conductor in the first cell is coupled to a gate of a first transistor in the first cell; routing a second conductive layer, which is higher than the first conductive layer, such that: a second conductor is in the second cell and adjoins the cell boundary, a pin conductor is in the first cell and adjoins the cell boundary, and the second conductor extends in the second cell and is coupled between a source/drain region of a second transistor in the second cell and the pin conductor; and routing a third conductive layer, which is higher than the second conductive layer, such that: a third conductor is in the first cell and forms at least a portion of a conductive path in the first cell between the first conductor and the second conductor, the third conductor being spaced apart from the cell boundary, and the third conductive layer is a highest conductive layer among conductive layers forming the conductive path in the first cell. In some embodiments, the storage medium 1104 further stores instructions therein that, when executed by the processor 1102, cause the processor 1102 to evaluate whether a second routing operation of the net would result in an antenna rule violation for the first transistor, and perform the first routing operation instead of the second routing operation when the evaluation determines that the second routing operation would result in the antenna rule violation for the first transistor.

The processor 1102 is electrically coupled to the storage medium 1104 via a bus 1108. The processor 1102 is also electrically coupled to an I/O interface 1110 via the bus 1108. A network interface 1112 is also electrically connected to the processor 1102 via the bus 1108. The network interface 1112 is connected to a network 1114, so that the processor 1102 and the storage medium 1104 are capable of connecting to external elements via the network 1114. The processor 1102 is configured to execute the instructions 1106 encoded in the storage medium 1104 in order to cause the EDA system 1100 to be usable for performing a portion or all of the noted processes and/or methods. In one or more embodiments, the processor 1102 is a central processing unit (CPU), a multi-processor, a distributed processing system, an application specific integrated circuit (ASIC), and/or a suitable processing unit.

In one or more embodiments, the storage medium 1104 is an electronic, magnetic, optical, electromagnetic, infrared, and/or a semiconductor system (or apparatus or device). In some embodiments, the storage medium 1104 includes a semiconductor or solid-state memory, a magnetic tape, a removable computer diskette, a random-access memory (RAM), a read-only memory (ROM), a rigid magnetic disk, and/or an optical disk. In one or more embodiments using optical disks, the storage medium 1104 includes a compact disc read-only memory (CD-ROM), a compact disc-read/write (CD-R/W), and/or a digital video disc (DVD).

In one or more embodiments, the storage medium 1104 stores the instructions 1106 configured to cause the EDA system 1100 (where such execution represents (at least in part) the EDA tool) to be usable for performing a portion or all of the noted processes and/or methods. In one or more embodiments, the storage medium 1104 also stores information that facilitates performing a portion or all of the noted processes and/or methods. In one or more embodiments, the storage medium 1104 stores a library 1107 of standard cells including such standard cells as disclosed herein. In one or more embodiments, the storage medium 1104 stores one or more layout diagrams 1109 corresponding to one or more layouts disclosed herein.

The EDA system 1100 includes the I/O interface 1110. The I/O interface 1110 is coupled to external circuitry. In one or more embodiments, the I/O interface 1110 includes a keyboard, keypad, mouse, trackball, trackpad, touchscreen, and/or cursor direction keys for communicating information and commands to the processor 1102.

The EDA system 1100 also includes the network interface 1112 coupled to the processor 1102. The network interface 1112 allows the EDA system 1100 to communicate with the network 1114, to which one or more other computer systems are connected. The network interface 1112 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more EDA systems 1100.

The EDA system 1100 is configured to receive information through the I/O interface 1110. The information received through the I/O interface 1110 includes one or more of instructions, data, design rules, libraries of standard cells, and/or other parameters for processing by the processor 1102. The information is transferred to the processor 1102 via the bus 1108. The EDA system 1100 is configured to receive information related to a user interface (UI) through the I/O interface 1110. The information is stored in the storage medium 1104 as a user interface (UI) 1142.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by the EDA system 1100. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 12 is a block diagram of the IC manufacturing system 1200, and an IC manufacturing flow associated therewith according to some embodiments. In some embodiments, based on a layout diagram, at least one of (A) one or more semiconductor masks or (B) at least one component in a layer of a semiconductor integrated circuit is fabricated using the IC manufacturing system 1200.

In FIG. 12, the IC manufacturing system 1200 includes entities, such as a design house 1220, a mask house 1230, and an IC manufacturer/fabricator (“fab”) 1250, that interact with one another in the design, development, and manufacturing cycles and/or services related to manufacturing an IC device 1260. The entities in the IC manufacturing system 1200 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of the design house 1220, the mask house 1230, and the IC fab 1250 is owned by a single larger company. In some embodiments, two or more of the design house 1220, the mask house 1230, and the IC fab 1250 coexist in a common facility and use common resources.

The design house (or design team) 1220 generates an IC design layout diagram 1222 based on the noted processes and/or methods discussed above. The IC design layout diagram 1222 includes various geometrical patterns that correspond to patterns of metal, oxide, or semiconductor layers that make up the various components of the IC device 1260 to be fabricated. The various layers combine to form various IC features. For example, a portion of the IC design layout diagram 1222 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. The design house 1220 implements a proper design procedure to form the IC design layout diagram 1222. The design procedure includes one or more of logic design, physical design or place and route. The IC design layout diagram 1222 is presented in one or more data files having information of the geometrical patterns. For example, the IC design layout diagram 1222 can be expressed in a GDSII file format or DFII file format.

The mask house 1230 includes mask data preparation 1232 and mask fabrication 1244. The mask house 1230 uses the IC design layout diagram 1222 to manufacture one or more masks 1245 to be used for fabricating the various layers of the IC device 1260 according to the IC design layout diagram 1222. The mask house 1230 performs the mask data preparation 1232, where the IC design layout diagram 1222 is translated into a representative data file (RDF). The mask data preparation 1232 provides the RDF to the mask fabrication 1244. The mask fabrication 1244 includes a mask writer. A mask writer converts the RDF to an image on a substrate, such as a mask (reticle) 1245 or a substrate 1253, e.g., a semiconductor wafer. The IC design layout diagram 1222 is manipulated by the mask data preparation 1232 to comply with particular characteristics of the mask writer and/or requirements of the IC fab 1250. In FIG. 12, the mask data preparation 1232 and the mask fabrication 1244 are illustrated as separate elements. In some embodiments, the mask data preparation 1232 and the mask fabrication 1244 can be collectively referred to as mask data preparation.

In some embodiments, the mask data preparation 1232 includes optical proximity correction (OPC) which uses lithography enhancement techniques to compensate for image errors, such as those that can arise from diffraction, interference, other process effects and the like. OPC adjusts the IC design layout diagram 1222. In some embodiments, the mask data preparation 1232 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 1232 includes a mask rule checker (MRC) that checks the IC design layout diagram 1222 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1222 to compensate for limitations during the mask fabrication 1244, which may undo part of the modifications performed by OPC in order to meet mask creation rules.

In some embodiments, the mask data preparation 1232 includes lithography process checking (LPC) that simulates processing that will be implemented by the IC fab 1250 to fabricate the IC device 1260. LPC simulates this processing based on the IC design layout diagram 1222 to create a simulated manufactured device, such as the IC device 1260. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine the IC design layout diagram 1222.

It should be understood that the above description of the mask data preparation 1232 has been simplified for the purposes of clarity. In some embodiments, the mask data preparation 1232 includes additional features such as a logic operation (LOP) to modify the IC design layout diagram 1222 according to manufacturing rules. Additionally, the processes applied to the IC design layout diagram 1222 during the mask data preparation 1232 may be executed in a variety of different orders.

After the mask data preparation 1232 and during the mask fabrication 1244, a mask 1245 or a group of masks 1245 are fabricated based on the modified IC design layout diagram 1222. In some embodiments, the mask fabrication 1244 includes performing one or more lithographic exposures based on the IC design layout diagram 1222. In some embodiments, an electron-beam (e-beam) or a mechanism of multiple e-beams is used to form a pattern on a mask (photomask or reticle) 1245 based on the modified IC design layout diagram 1222. The mask 1245 can be formed in various technologies. In some embodiments, the mask 1245 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of the mask 1245 includes a transparent substrate (e.g., fused quartz) and an opaque material (e.g., chromium) coated in the opaque regions of the binary mask. In another example, the mask 1245 is formed using a phase shift technology. In a phase shift mask (PSM) version of the mask 1245, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 1244 is used in a variety of processes. For example, in some embodiments the mask(s) is used in an ion implantation process to form various doped regions in the substrate 1253, in an etching process to form various etching regions in the substrate 1253, and/or in other suitable processes.

The IC fab 1250 is an IC fabrication business that includes one or more manufacturing facilities for the fabrication of a variety of different IC products. In some embodiments, the IC fab 1250 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

The IC fab 1250 includes wafer fabrication tools 1252 configured to execute various manufacturing operations on the substrate 1253 such that the IC device 1260 is fabricated in accordance with the mask(s), e.g., the mask 1245. In some embodiments, the wafer fabrication tools 1252 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

The IC fab 1250 uses mask(s) 1245 fabricated by the mask house 1230 to fabricate the IC device 1260. Thus, the IC fab 1250 at least indirectly uses the IC design layout diagram 1222 to fabricate the IC device 1260. In some embodiments, the substrate 1253 is fabricated by the IC fab 1250 using mask(s) 1245 to form the IC device 1260. In some embodiments, the IC fabrication includes performing one or more lithographic exposures based at least indirectly on the IC design layout diagram 1222. In some embodiments, the substrate 1253 includes a silicon substrate or other proper substrate having material layers formed thereon. In some embodiments, the substrate 1253 further includes one or more of various doped regions, dielectric features, multilevel interconnects, and the like (formed at subsequent manufacturing steps).

Details regarding an IC manufacturing system (e.g., IC manufacturing system 1200 of FIG. 12), and an IC manufacturing flow associated therewith are found, e.g., in U.S. Pat. No. 9,256,709, granted Feb. 9, 2016, U.S. Pre-Grant Publication No. 2015/0278429 A1, published Oct. 1, 2015, U.S. Pre-Grant Publication No. 2014/0040838 A1, published Feb. 6, 2014, and U.S. Pat. No. 7,260,442, granted Aug. 21, 2007, the entireties of each of which are hereby incorporated by reference.

In some embodiments, a semiconductor structure includes: a plurality of nanostructures over a substrate; a dielectric feature over the plurality of nanostructures; a gate structure wrapping around the plurality of nanostructure and the dielectric feature; and inner spacers on opposite sides of the gate structure and below the dielectric feature.

In some embodiments, a semiconductor device includes: first, second, and third transistor stacks on a substrate, the second transistor stack being between the first transistor stack and the third transistor stack relative to a first direction. The first and third transistor stacks each include a first semiconductor nanosheet, a second semiconductor nanosheet, and a third semiconductor nanosheet, all wrapped by a common gate, the third semiconductor nanosheet being higher than the first and second semiconductor nanosheets relative the substrate, and the second transistor stack includes the first semiconductor nanosheet, the second semiconductor nanosheet, and the common gate, and is free of the third semiconductor nanosheet.

In some embodiments, a method of fabricating a semiconductor device includes: forming first, second, and third transistor stacks on a substrate, the second transistor stack being formed between the first transistor stack and the third transistor stack relative to a first direction, wherein: forming each of the first, second, and third transistor stacks includes: forming a first semiconductor nanosheet, a first spacer, a second semiconductor nanosheet, a second spacer, and a third semiconductor nanosheet in the stated order with the first semiconductor nanosheet being closer to the substrate than the first spacer; and forming the second transistor stack further includes: replacing the third semiconductor nanosheet with a dielectric material.

In some embodiments, a semiconductor device includes a first source/drain structure on a substrate; a second source/drain structure on the substrate and spaced apart from the first source/drain structure in a first direction; a first portion of a first channel structure adjacent the first source/drain structure at a first distance from the substrate; a second portion of the first channel structure adjacent the second source/drain structure, the second portion of the first channel structure being at the first distance from the substrate and spaced apart from the first portion of the first channel structure in the first direction; an insulating structure between the first and second portions of the first channel structure relative to the first direction, the insulating structure being at the first distance from the substrate and having a thickness that is at least as thick as either of the first and second portions of the first channel structure; and a second channel structure between the first and second source/drain structures at a second distance from the substrate, the second distance being less than the first distance.

In some embodiments, the insulating structure includes an insulating material that is other than an oxide of a material included in the first and second portions of the first channel structure. In some embodiments, the insulating structure includes a material that has a higher dielectric constant than an oxide of a material included in the first and second portions of the first channel structure. In some embodiments, the semiconductor device further includes: a first stack of a number n of channel structures that is greater than 1, the n channel structures being spaced apart in a vertical direction; a first gate at least partially surrounding the n channel structures; a second stack of a number n-1 of channel structures, the n-1 channel structures being spaced apart in the vertical direction and including the second channel structure; and a second gate at least partially surrounding the first and second portions of the first channel structure and the n-1 channel structures. In some embodiments, the first and second portions of the first channel structure are at a same distance from the substrate as an uppermost channel structure of the n channel structures, the first source/drain structure is at a first side of the second gate and the second source/drain structure is at a second side of the second gate, the n-1 channel structures being configured to selectively conduct current between the first and second source/drain structures, e.g., when a signal is applied to the second gate, and the insulating structure is at least partially surrounded by the second gate. In some embodiments, the insulating structure is configured to block a current path between the first and second source/drain structures at a level of the uppermost channel structure. In some embodiments, the semiconductor device further includes a gate dielectric layer that at least partially surrounds the insulating structure. In some embodiments, the insulating structure protrudes through an opening in the gate dielectric layer in a direction extending away from the substrate. In some embodiments, the semiconductor device further includes a third source/drain structure spaced apart from the second source/drain structure. The n channel structures are between the second source/drain structure and the third source/drain structure, and are configured to selectively conduct current between the second source/drain structure and the third source/drain structure, e.g., when a signal is applied to the first gate. In some embodiments, the first and second portions of the first channel structure are lightly-doped drain regions.

In some embodiments, a method of fabricating a semiconductor device includes: forming a first source/drain structure and a second source/drain structure spaced apart in a first direction on a substrate; forming at least first and second channel structures spaced apart relative to a second direction perpendicular to the substrate, the first channel structure being an uppermost channel structure of the at least first and second channel structures, the first and second source/drain structures and the at least first and second channel structures being formed such that the first and second source/drain structures have the at least first and second channel structures therebetween; removing part of the first channel structure such that a first portion of the first channel structure remains adjacent the first source/drain structure at a first distance from the substrate, and a second portion of the first channel structure remains adjacent the second source/drain structure at the first distance from the substrate and spaced apart from the first portion of the first channel structure in the first direction; and forming an insulating structure between the first and second portions of the first channel structure relative to the first direction, the insulating structure being at the first distance from the substrate and being formed to have a thickness that is at least as thick as either of the first and second portions of the first channel structure.

In some embodiments, forming the insulating structure includes depositing an insulating material that is other than an oxide of a material used to form the first channel structure. In some embodiments, forming the insulating structure includes depositing a material that has a higher dielectric constant than an oxide of a material used to form the first channel structure. In some embodiments, the method further includes: forming a first stack of a number n of channel structures spaced apart in a vertical direction, n being greater than 1; forming a first gate at least partially surrounding the n channel structures; and forming a second gate at least partially surrounding the first and second portions of the first channel structure and the second channel structure. The first and second portions of the first channel structure are at a same distance from the substrate as an uppermost channel structure of the n channel structures, the first source/drain structure is at a first side of the second gate and the second source/drain structure is at a second side of the second gate, the second channel structure being configured to selectively conduct current between the first and second source/drain structures, e.g., when a signal is applied to the second gate, and the insulating structure is at least partially surrounded by the second gate. In some embodiments, the removing part of the first channel structure and the forming the insulating structure blocks a current path between the first and second source/drain structures. In some embodiments, the method further includes forming a gate dielectric layer to at least partially surround the insulating structure. In some embodiments, the method further includes forming a third source/drain structure spaced apart from the second source/drain structure. The n channel structures are between the second source/drain structure and the third source/drain structure, and are configured to selectively conduct current between the second source/drain structure and the third source/drain structure, e.g., when a signal is applied to the first gate.

In some embodiments, a semiconductor device includes: a first stack of a number n of channel structures that is greater than 1, the n channel structures being spaced apart in a vertical direction; a first gate at least partially surrounding the n channel structures; a second stack of a number n-1 of channel structures, the n-1 channel structures being spaced apart in the vertical direction; a second gate at least partially surrounding the n-1 channel structures; a first source/drain structure at a first side of the second gate and a second source/drain structure at a second side of the second gate, the n-1 channel structures being configured to selectively conduct current between the first and second source/drain structures, e.g., when a signal is applied to the second gate; and an insulating structure at least partially surrounded by the second gate, the insulating structure being between the first and second source/drain structures at a same level as an uppermost channel structure of the n channel structures in the first stack of n channel structures, the insulating structure blocking a current path between the first and second source/drain structures at a level of the uppermost channel structure.

In some embodiments, the insulating structure includes a material that has a higher dielectric constant than an oxide of a material included in the uppermost channel structure. In some embodiments, the insulating structure contacts sidewalls of the first and second source/drain structures. In some embodiments, a gate dielectric layer partially surrounds the insulating structure, and the insulating structure protrudes through an opening in the gate dielectric layer.

In some embodiments, a semiconductor device includes: a first source/drain structure; a second source/drain structure; a first gate stack on a first side of the second source/drain structure, between the first and second source/drain structures, the first gate stack being configured to control a current flowing from the first source/drain structure to the second source/drain structure; a third source/drain structure; a second gate stack between the second and third source/drain structures and configured to control a current flowing from the second source/drain structure to the third source/drain structure, the second gate stack having a stack of n channel regions extending between the first and second source/drain structures, n being two or more, the first gate stack having a stack of n-1 channel regions extending between the first and second source/drain structures, and the first gate stack having an insulating structure extending between the second and third source/drain structures at a same height as an uppermost one of the n channel regions of the second gate stack, the insulating structure being in contact with sidewalls of the second and third source/drain structures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first source/drain structure on a substrate;
a second source/drain structure on the substrate and spaced apart from the first source/drain structure in a first direction;
a first portion of a first channel structure adjacent the first source/drain structure at a first distance from the substrate;
a second portion of the first channel structure adjacent the second source/drain structure, the second portion of the first channel structure being at the first distance from the substrate and spaced apart from the first portion of the first channel structure in the first direction;
an insulating structure between the first and second portions of the first channel structure relative to the first direction, the insulating structure being at the first distance from the substrate and having a thickness that is at least as thick as either of the first and second portions of the first channel structure; and
a second channel structure between the first and second source/drain structures at a second distance from the substrate, the second distance being less than the first distance.

2. The semiconductor device of claim 1, wherein:
the insulating structure includes an insulating material that is other than an oxide of a material included in the first and second portions of the first channel structure.

3. The semiconductor device of claim 1, wherein:
the insulating structure includes a material that has a higher dielectric constant than an oxide of a material included in the first and second portions of the first channel structure.

4. The semiconductor device of claim 1, further comprising:
a first stack of a number n of channel structures that is greater than 1, the n channel structures being spaced apart in a vertical direction;
a first gate at least partially surrounding the n channel structures;
a second stack of a number n-1 of channel structures, the n-1 channel structures being spaced apart in the vertical direction and including the second channel structure; and
a second gate at least partially surrounding the first and second portions of the first channel structure and the n-1 channel structures,
wherein:
the first and second portions of the first channel structure are at a same distance from the substrate as an uppermost channel structure of the n channel structures,
the first source/drain structure is at a first side of the second gate and the second source/drain structure is at a second side of the second gate, the n-1 channel structures being configured to selectively conduct current between the first and second source/drain structures, and
the insulating structure is at least partially surrounded by the second gate.

5. The semiconductor device of claim 4, wherein:
the insulating structure is configured to block a current path between the first and second source/drain structures at a level of the uppermost channel structure.

6. The semiconductor device of claim 4, further comprising:
a gate dielectric layer that at least partially surrounds the insulating structure.

7. The semiconductor device of claim 6, wherein:
the insulating structure protrudes through an opening in the gate dielectric layer in a direction extending away from the substrate.

8. The semiconductor device of claim 4, further comprising:
a third source/drain structure spaced apart from the second source/drain structure, wherein:
the n channel structures are between the second source/drain structure and the third source/drain structure, and are configured to selectively conduct current between the second source/drain structure and the third source/drain structure.

9. The semiconductor device of claim 1, wherein:
the first and second portions of the first channel structure are lightly-doped drain regions.

10. A method of fabricating a semiconductor device, the method comprising:
forming a first source/drain structure and a second source/drain structure spaced apart in a first direction on a substrate;
forming at least first and second channel structures spaced apart relative to a second direction perpendicular to the substrate, the first channel structure being an uppermost channel structure of the at least first and second channel structures,
wherein the first and second source/drain structures and the at least first and second channel structures are formed such that the first and second source/drain structures have the at least first and second channel structures therebetween;
removing part of the first channel structure such that a first portion of the first channel structure remains adjacent the first source/drain structure at a first distance from the substrate, and a second portion of the first channel structure remains adjacent the second source/drain structure at the first distance from the substrate and spaced apart from the first portion of the first channel structure in the first direction; and
forming an insulating structure between the first and second portions of the first channel structure relative to the first direction, the insulating structure being at the first distance from the substrate and being formed to have a thickness that is at least as thick as either of the first and second portions of the first channel structure.

11. The method of claim 10, wherein:
forming the insulating structure includes depositing an insulating material that is other than an oxide of a material used to form the first channel structure.

12. The method of claim 10, wherein:
forming the insulating structure includes depositing a material that has a higher dielectric constant than an oxide of a material used to form the first channel structure.

13. The method of claim 10, further comprising:
forming a first stack of a number n of channel structures spaced apart in a vertical direction, n being greater than 1;
forming a first gate at least partially surrounding the n channel structures; and
forming a second gate at least partially surrounding the first and second portions of the first channel structure and the second channel structure,
wherein:
the first and second portions of the first channel structure are at a same distance from the substrate as an uppermost channel structure of the n channel structures,
the first source/drain structure is at a first side of the second gate and the second source/drain structure is at a second side of the second gate, the second channel structure being configured to conduct current between the first and second source/drain structures when a signal is applied to the second gate, and
the insulating structure is at least partially surrounded by the second gate.

14. The method of claim 13, wherein:
the removing part of the first channel structure and the forming the insulating structure blocks a current path between the first and second source/drain structures.

15. The method of claim 13, further comprising:
forming a gate dielectric layer to at least partially surround the insulating structure.

16. The method of claim 15, further comprising:
forming a third source/drain structure spaced apart from the second source/drain structure, wherein:
the n channel structures are between the second source/drain structure and the third source/drain structure, and are configured to conduct current between the second source/drain structure and the third source/drain structure when a signal is applied to the first gate.

17. A semiconductor device comprising:
a first stack of a number n of channel structures that is greater than 1, the n channel structures being spaced apart in a vertical direction;
a first gate at least partially surrounding the n channel structures;
a second stack of a number n-1 of channel structures, the n-1 channel structures being spaced apart in the vertical direction;
a second gate at least partially surrounding the n-1 channel structures;
a first source/drain structure at a first side of the second gate and a second source/drain structure at a second side of the second gate, the n-1 channel structures being configured to selectively conduct current between the first and second source/drain structures; and
an insulating structure at least partially surrounded by the second gate, the insulating structure being between the first and second source/drain structures at a same level as an uppermost channel structure of the n channel structures in the first stack of n channel structures, the insulating structure blocking a current path between the first and second source/drain structures at a level of the uppermost channel structure.

18. The semiconductor device of claim 17, wherein:
the insulating structure includes a material that has a higher dielectric constant than an oxide of a material included in the uppermost channel structure.

19. The semiconductor device of claim 17, wherein:
the insulating structure contacts sidewalls of the first and second source/drain structures.

20. The semiconductor device of claim 17, wherein:
a gate dielectric layer partially surrounds the insulating structure, and the insulating structure protrudes through an opening in the gate dielectric layer.
